(19) United States
(12) Patent Application Publication
(10) Pub. No.: US 2026/0312480 A1
(43) Pub. Date: Oct. 8, 2026

(54) SINGLE-ENDED DRIVER AND BIDIRECTIONAL OVERCURRENT PROTECTION FOR A THERMOELECTRIC COOLER

(71) Applicant: Texas Instruments Incorporated, Dallas, TX (US)

(72) Inventors: Hariharan Srinivasan, Chennai (IN); Madhur Sharma, Bangalore (IN); Gautam Salil Nandi, Bangalore (IN)

(21) Appl. No.: 19/426,938

(22) Filed: Dec. 19, 2025

(30) Foreign Application Priority Data
Apr. 8, 2025 (IN) 202541034510
Apr. 8, 2025 (IN) 202541034609

(51) Int. Cl. H02M 1/088; H01S 5/024; H02M 1/00; H02M 1/08; H02M 3/157; H02M 3/158

(52) U.S. Cl. CPC H02M 1/088; H01S 5/02415; H02M 1/0009; H02M 1/083; H02M 3/157; H02M 3/1582

(57) ABSTRACT

In accordance to an embodiment, an electronic circuit includes: first and second supply terminals; first and second inductor terminals; an output terminal; a first switch coupled between the first supply terminal and the first inductor terminal; a second switch coupled between the first inductor terminal and the second supply terminal; a third switch coupled between the first supply terminal and the second inductor terminal; a fourth switch coupled between the second inductor terminal and the output terminal; and a controller configured to: when an output voltage at the output terminal is higher than a first threshold, close the fourth switch, open the third switch, and operate the first and second switches in alternate phases; when the output voltage is lower than a second threshold that is lower than the first threshold, close the second switch, open the first switch, and operate the third and fourth switches in alternate phases; and when the output voltage is between the first and second thresholds, operate the first and fourth switches according to a first clock signal, and operate the second and third switches according to a second clock signal that is non-overlapping with respect to the first clock signal.

### CROSS-REFERENCE TO RELATED APPLICATION

This patent application claims the benefit of and priority to Indian Provisional Patent Application No. 202541034510, filed Apr. 8, 2025, and Indian Provisional Patent Application No. 202541034609, filed Apr. 8, 2025, which are hereby incorporated herein by reference in their entireties.

### TECHNICAL FIELD

This description relates generally to an electronic system and method, and, in particular embodiments, to a single-ended driver and bidirectional overcurrent protection for a thermoelectric cooler.

### BACKGROUND

Laser diodes are used in optical communication systems for sending signals across a fiber optic cable. To ensure stable laser characteristics, the temperature across a laser diode has to be maintained at a relatively constant level during operation. For example, the target relative temperature error for a laser diode is less than five millidegrees Celsius (<5 m° C.) in telecommunications applications. To control the temperature of a laser diode, telecommunications systems include a thermoelectric cooler (TEC) element. A TEC can either heat or cool a laser diode depending on the direction of current passing through the TEC. To ensure temperature stability of a laser diode, a TEC is coupled to a control loop that regulates the heat generated or absorbed by the TEC.

### SUMMARY

In accordance to an embodiment, an electronic circuit includes: first and second supply terminals; first and second inductor terminals; an output terminal; a first switch coupled between the first supply terminal and the first inductor terminal; a second switch coupled between the first inductor terminal and the second supply terminal; a third switch coupled between the first supply terminal and the second inductor terminal; a fourth switch coupled between the second inductor terminal and the output terminal; and a controller configured to: when an output voltage at the output terminal is higher than a first threshold, close the fourth switch, open the third switch, and operate the first and second switches in alternate phases; when the output voltage is lower than a second threshold that is lower than the first threshold, close the second switch, open the first switch, and operate the third and fourth switches in alternate phases; and when the output voltage is between the first and second thresholds, operate the first and fourth switches according to a first clock signal, and operate the second and third switches according to a second clock signal that is non-overlapping with respect to the first clock signal.

In accordance to an embodiment, an electronic circuit includes: first and second supply terminals; first and second inductor terminals; an output terminal coupled to the second inductor terminal; a first transistor having a current path coupled between the first supply terminal and the first inductor terminal; a second transistor having a current path coupled between the first inductor terminal and the second supply terminal; and a current sensing circuit including: a third transistor having a control terminal coupled to a control terminal of the first transistor, and a first current path terminal coupled to the first supply terminal; a first amplifier having a first input coupled to a second current path terminal of the third transistor, and a second input coupled to the current path of the first transistor; a fourth transistor having a first current path terminal coupled to the second current path terminal of the third transistor, and a control terminal coupled to an output of the first amplifier; a second amplifier having a first input coupled to a second current path terminal of the fourth transistor; and a first resistor coupled to the second current path terminal of the fourth transistor.

In accordance to an embodiment, a method includes: operating first and second switches with a fixed switching frequency to regulate an output voltage at an output terminal, where the first switch is coupled between a first supply terminal and a first inductor terminal, where the second switch is coupled between the first inductor terminal and a second supply terminal, where an inductor is coupled between the first inductor terminal and a second inductor terminal, and where the output terminal is coupled to the second inductor terminal; in response to inductor current through the inductor being higher than a first current threshold, turning off the first switch and turning on the second switch to start a first discharge phase of the inductor; during the first discharge phase of the inductor, maintain the first switch off and the second switch on; and in response to the inductor current dropping below a second current threshold that is lower than the first current threshold, restarting operation of the first and second switches with the fixed switching frequency to exit the first discharge phase.

In accordance to an embodiment, an electronic circuit includes: first and second supply terminals; first and second inductor terminals; an output terminal coupled to the second inductor terminal; a first transistor having a current path coupled between the first supply terminal and the first inductor terminal; a second transistor having a current path coupled between the first inductor terminal and the second supply terminal; and a current sensing circuit including: a third transistor having a first current path terminal, a second current path terminal, and a control terminal coupled to a control terminal of the second transistor, the second current path terminal coupled to the second supply terminal; a first amplifier having a first input coupled to the first current path terminal of the third transistor, and a second input coupled to the current path of the second transistor; a fourth transistor having a first current path terminal coupled to the first current path terminal of the third transistor, and a control terminal coupled to an output of the first amplifier; a second amplifier having a first input coupled to a second current path terminal of the fourth transistor; and a first resistor coupled to the second current path terminal of the fourth transistor.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a block diagram of an example system including an example thermoelectric cooler (TEC) element and an example driver power stage for the TEC element, according to an embodiment of the present disclosure;

FIG. 2 is a schematic diagram of the driver power stage of FIG. 1, according to an embodiment of the present disclosure;

FIG. 3 is a schematic diagram of an example configuration of the driver power stage of FIG. 2 in forward mode (also referred to as buck mode), according to an embodiment of the present disclosure;

FIG. 4 is a schematic diagram of an example configuration of the driver power stage of FIG. 2 in reverse mode (also referred to as inverting buck-boost mode), according to an embodiment of the present disclosure;

FIG. 5 is a schematic diagram of the driver power stage of FIG. 2 where the first through fourth switches are implemented by example N-channel metal-oxide semiconductor (NMOS) transistors, according to an embodiment of the present disclosure;

FIG. 6 is a schematic diagram of the driver power stage of FIG. 2 where the second and fourth switches are implemented by example NMOS transistors and the first and third switches are implemented by example P-channel metal-oxide semiconductor (PMOS) transistors, according to an embodiment of the present disclosure;

FIG. 7 is a timing diagram depicting possible inductor current in the driver power stage of FIG. 2;

FIG. 8 is a block diagram of an example system including an example controller for the driver power stage of FIG. 2 and an example overcurrent (OI) current sensor subsystem for the driver power stage, according to an embodiment of the present disclosure;

FIG. 9 is a schematic diagram of the high-side source mode sensor of FIG. 8, according to an embodiment of the present disclosure;

FIG. 10 is a schematic diagram of an example calibration circuit for the high-side source mode OI comparator of FIG. 8, according to an embodiment of the present disclosure;

FIG. 11 is a schematic diagram of the low-side source mode sensor of FIG. 8, according to an embodiment of the present disclosure;

FIG. 12 is a schematic diagram of the low-side sink mode sensor of FIG. 8 and an example calibration circuit for the low-side sink mode OI comparator of FIG. 8, according to an embodiment of the present disclosure;

FIG. 13 is a schematic diagram of the high-side sink mode sensor of FIG. 8, according to an embodiment of the present disclosure;

FIG. 14 is a schematic diagram of the source mode state machine of FIG. 8, according to an embodiment of the present disclosure;

FIG. 15 is a schematic diagram of the sink mode state machine of FIG. 8, according to an embodiment of the present disclosure;

FIG. 16 is a timing diagram depicting example undercurrent (UI) protection and OI protection of the driver power stage of FIG. 2 in source mode during buck mode operation, according to an embodiment of the present disclosure;

FIG. 17 is a timing diagram depicting example UI protection and OI protection of the driver power stage of FIG. 2 in sink mode during intermediate mode operation, according to an embodiment of the present disclosure; and

FIG. 18 is a timing diagram depicting example UI protection and OI protection of the driver power stage of FIG. 2 in sink mode during inverting buck-boost mode operation, according to an embodiment of the present disclosure.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be obtained without one or more of the specific details, or with other methods, components, materials, and the like. In some cases, known structures, materials, or operations are not shown or described in detail so as not to obscure the different aspects of the embodiments. References to “an embodiment” or “an example” in this description indicate that a particular configuration, structure, or feature described in relation to the embodiment is included in at least one embodiment. Consequently, phrases such as “in one embodiment” or “in one example” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

Laser diodes are used in optical communication systems for sending signals across a fiber optic cable. To ensure stable laser characteristics, a driver power stage is used to control the voltage across or the current through a thermoelectric cooler (TEC) element to maintain a relatively constant temperature of a laser diode (e.g., within <5 m° C. of a target temperature). A TEC element is a solid-state device that transfers heat from one side of the TEC element to the other side of the TEC element based on electrical energy consumption by the TEC element. For example, a TEC element utilizes the thermoelectric effect, specifically the Peltier effect, to transfer heat from one side of the TEC element to the other depending on the polarity of the TEC element with respect to the applied voltage or current.

TEC elements are driven by differential driver power stages. For example, each of the two terminals of a TEC element is coupled to a supply terminal of a driver power stage and the driver power stage controls the voltages at each of the supply terminals to control the current through and the voltage across the TEC element. Driving a TEC element via differential supply terminals and without inductor capacitor (LC) filter(s) at the output increases the power dissipated by the TEC element and therefore decreases the efficiency of power transfer to the TEC element. In laser diode applications, the driver power stage of a TEC element is expected to generate a controlling voltage across the TEC element while achieving high power transfer efficiency (e.g., >90%).

To improve the efficiency of a differential driver power stage, LC filters can be added to the supply terminals of the driver power stage. However, the added LC filters occupy additional board space and increase the overall monetary cost of a TEC system (e.g., a TEC driver (including the driver power stage) and a TEC element). Additionally, the equivalent series resistance (ESR) of the added inductors of the LC filters increases power loss of the TEC system. Other differential driver power stages only include a single LC filter which reduces the amount of occupied board space and reduces the monetary cost of a TEC system. However, such differential driver power stages suffer from a glitchy zero-crossing due to the asymmetric driving architecture.

A glitchy zero-crossing refers to overshoot or undershoot of the target voltage or target current when the voltage across or the current through a TEC element transitions across zero. A glitchy zero-crossing poses multiple challenges at the application level. For example, voltage or current overshoot during zero-crossing propagates to the TEC element and creates a momentary glitch in the temperature of a laser diode that is large enough to be detected as a disturbance in telecommunication. Voltage or current overshoot can also couple to a silicon substrate or printed circuit board (PCB) traces and act as common mode noise that couples to a negative temperature coefficient (NTC) of a thermistor utilized to monitor laser diode temperature. Common mode noise coupled to the NTC causes temperature measurements based on the thermistor to be momentarily incorrect.

Hardware filters can be added to prevent glitchy zero-crossing. However, adding hardware filters occupies additional board space, which is very limited in optical transceivers. Additionally, adding hardware filters increases the monetary cost of a TEC system. Another approach to prevent glitchy zero-crossing is to reduce the operational frequency of a differential driver power stage when conducting a zero-crossing. In this manner, a driver power stage slowly (compared to normal operation) transitions the voltage or current provided by the driver power stage to a target voltage or target current. This approach is implemented empirically or on an ad hoc basis, which requires lengthy development time to ensure reliable operation.

Embodiments of the present disclosure are described in specific contexts, e.g., a driver power stage for a TEC element. Some embodiments may be used in other circuits, such as a power electronics circuit, a driver circuit for a power transistor, and/or a monitoring circuit for a power transistor. Some embodiments include a single ended driver power stage that controls a TEC element in three modes of operation depending on the output voltage from the driver power stage. As such, some embodiments advantageously meet the target power transfer efficiency for laser diode applications while reducing TEC system cost, reducing board space consumption, and providing glitch-free zero-crossing. Accordingly, some embodiments advantageously reduce TEC system cost, reduce the number of off-chip components, and reduce board area consumption and total system size.

Some embodiments monitor for undercurrent events during discharging phases in addition to monitoring for overcurrent events during charging phases to control inductor current in the driver power stage of a TEC system. In some embodiments, the current sensing does not require off-chip components or additional voltage sensing pins to sense inductor current. In some embodiments, the current sensing does not utilize a series lossy component to monitor current and thus, improves efficiency of TEC systems.

Some embodiments include calibrating as part of overcurrent monitoring to reduce DC error for overcurrent detection to a very low value (e.g., 25 milliamps). In some embodiments, the calibration is performed without drawing a large inductor current which reduces power loss during calibration. By avoiding large inductor current draw during calibration, some embodiments advantageously reduce the time and cost to perform calibration. For example, by avoiding large inductor current draw during calibration, test benches evaluating example TEC systems described herein may not require additional instruments to draw larger currents. Advantageously, in some embodiments, the calibration permits a comparator without a very low offset to be utilized for overcurrent monitoring. In some embodiments, the calibration is immune to switching noise. Accordingly, overcurrent monitoring according to some embodiments is very reliable across wide operating conditions. Overcurrent monitoring, according to some embodiments, is suitable for both fixed frequency and variable frequency (e.g., pulse-skip modulation) operation and can detect overcurrent in an inductor on a cycle-by-cycle basis in both positive and negative directions.

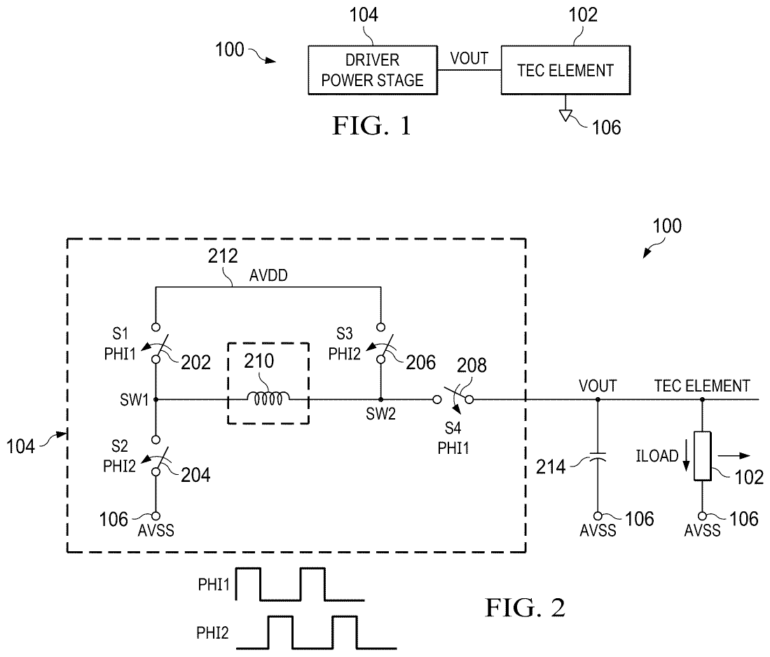

FIG. 1 is a block diagram of system 100, according to an embodiment of the present disclosure. System 100 includes thermoelectric cooler (TEC) element 102 and driver power stage 104 for the TEC element 102. In the example of FIG. 1, the driver power stage 104 is a single-ended driver power stage that controls the amount of heat transferred by the TEC element 102 in three modes of operation depending on an output voltage (VOUT) from the driver power stage 104. For example, the output voltage (VOUT) is measured with respect to an example common terminal 106. In the example of FIG. 1, the common terminal 106 is at a voltage of zero volts (V). For example, the common terminal 106 is an analog ground terminal such as a chassis ground terminal. In some examples, the common terminal 106 is referred to as a supply terminal or a reference terminal.

In the illustrated example of FIG. 1, the driver power stage 104 controls the amount of heat transferred by the TEC element 102 by controlling the voltage across or the current through the TEC element 102. For example, by varying the voltage across or the current through the TEC element 102 from negative to positive and vice versa, the driver power stage 104 can use the TEC element 102 to cool or heat a laser diode based on the polarity of the TEC element 102. The polarity of the TEC element 102 refers to how the TEC element 102 is coupled to the driver power stage 104. For example, if the positive terminal of the TEC element 102 is coupled to the output terminal of the driver power stage 104 and the negative terminal of the TEC element 102 is coupled to the common terminal 106, then the TEC element 102 has positive polarity. With positive polarity, the TEC element 102 acts as a heat source when positive voltages or currents are applied and acts as a heat sink when negative voltages or currents are applied.

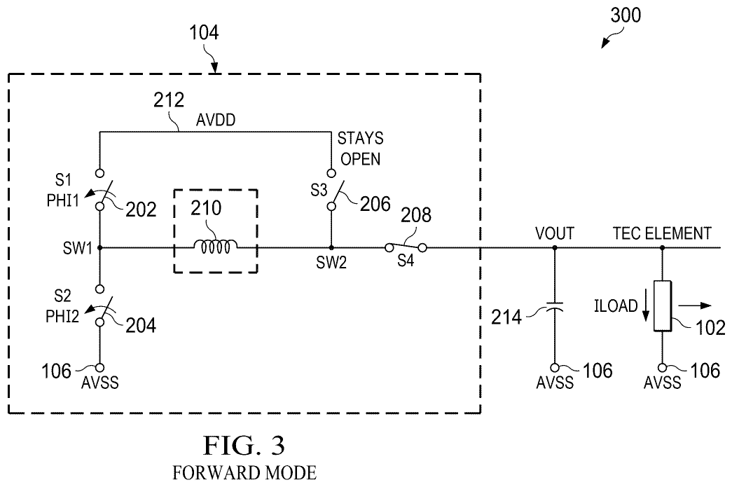

Alternatively, if the positive terminal of the TEC element 102 is coupled to the common terminal 106 and the negative terminal of the TEC element 102 is coupled to the output terminal of the driver power stage 104, then the TEC element 102 has negative polarity. With negative polarity, the TEC element 102 acts as a heat sink when positive voltages or currents are applied and acts as a heat source when negative voltages or currents are applied. With either polarity, the driver power stage 104 controls the TEC element 102 in three modes of operation in the example of FIG. 3. The three modes of operation include buck mode, inverting buck-boost mode, and intermediate mode.

For example, when the output voltage is greater than a first threshold (e.g., VOUT>V_{P}), the driver power stage 104 controls the TEC element 102 in a buck mode (also referred to as a forward mode) of operation. When the output voltage is less than a second threshold (e.g., VOUT<V_{M}), the driver power stage 104 controls the TEC element 102 in an inverting buck-boost mode (also referred to as a reverse mode) of operation. When the output voltage is between the first and second thresholds (e.g., V_{P}>VOUT>V_{M}), the driver power stage 104 controls the TEC element 102 in an intermediate mode of operation.

FIG. 2 is a schematic diagram of the driver power stage 104 of FIG. 1, according to an embodiment of the present disclosure. In the example of FIG. 2, the driver power stage 104 includes a first switch 202, a second switch 204, a third switch 206, and a fourth switch 208. In the example of FIG. 2, an inductor 210 is coupled between nodes SW1 and SW2. For example, the node SW1 is between the switch 202 and the switch 204 and the node SW2 is between the switch 206 and the switch 208. As such, the nodes SW1 and SW2 are referred to as first and second inductor terminals in some examples.

In the illustrated example of FIG. 2, the switches 202 and 206 (identified as S1 and S3, respectively) are high-side switches coupled to a supply terminal 212 (identified as AVDD). For example, the supply terminal 212 may be at a voltage between 3 V and 5.5 V. Also, the switch 204 (identified as S2) is a low-side switch coupled to the common terminal 106 (identified as AVSS). In the example of FIG. 2, the switch 208 (identified as S4) is a floating switch coupled to the load. For example, in FIG. 2, the load is the TEC element 102. Also, in the example of FIG. 2, the output terminal of the driver power stage 104 is coupled to an example capacitor 214 that smooths the output voltage (VOUT) to the TEC element 102.

As described above, the driver power stage 104 controls the TEC element 102 in three modes of operation: buck mode, inverting buck-boost mode, and intermediate mode. In the example of FIG. 2, the intermediate mode of operation includes a controller (described below) operating the driver power stage 104 in two phases using the PHI1 waveform (also referred to as PHI1) and the PHI2 waveform (also referred to as PHI2). For example, the PHI1 and PHI2 waveforms represent first and second clock signals that are non-overlapping with respect to one another (e.g., to avoid current shoot through from the supply terminal 212 to the common terminal 106). When operating in intermediate mode, the driver power stage 104 generates positive and negative voltages. Equation 1 below illustrates the direct current (DC) transfer relationship between the output voltage (VOUT) from the driver power stage 104 and the voltage at the supply terminal 212 (AVDD) in intermediate mode. In Equation 1, D represents the duty cycle of the waveform PHI1. The waveform PHI2 is the complement of PHI1 with an offset to create a deadtime between PHI1 and PHI2.

$$\frac{VOUT}{AVDD} = \frac{2 D - 1}{D} \qquad Equation 1$$

In the illustrated example of FIG. 2, for a duty cycle greater than 0.5 (e.g., D>0.5), the output voltage from the driver power stage 104 is positive (e.g., VOUT>0V). For a duty cycle less than 0.5 (e.g., D<0.5), the output voltage from the driver power stage 104 is negative (e.g., VOUT<0V). In the example of FIG. 2, for a duty cycle of 0.5 (e.g., D=0.5), the output voltage from the driver power stage 104 is zero volts (VOUT=0V). Thus, to ensure glitch-free zero-crossing, a controller for the driver power stage 104 (described below) sets the duty cycle to 0.5 when approaching a zero-crossing event. Duty cycles closer to 1 or 0 could result in glitchy zero-crossing as transitions would be impacted by finite rise time and finite fall times of the PHI1 and PHI2 waveforms.

In the illustrated example of FIG. 2, the open-loop characteristic of the driver power stage 104 is monotonic without any discontinuity near zero-crossing. For example, there is a linear relationship between the duty cycle and the output voltage (VOUT) where the output voltage (VOUT) increases or decreases linearly as the duty cycle increases or decreases, respectively. Thus, the driver power stage 104 provides glitch-free zero-crossing. Glitch-free zero-crossing refers to reaching a target voltage across or a target current through a TEC element without or with acceptable low overshoot or undershoot when the voltage across or the current through the TEC element transitions across zero. The monotonic behavior of the driver power stage 104, without discontinuity at the zero-crossing, along with a feedback loop from the TEC element 102 to a thermistor and controller (described below) ensures a seamless zero crossing in the temperature output from the TEC element 102.

In the illustrated example of FIG. 2, if the driver power stage 104 is operated exclusively in intermediate mode, the average current through the inductor 210 (IL_{avg}) would be greater than the current through the TEC element 102 (Iload) due to the switching of the switches 202-208

$$( e . g . , {IL}_{avg} = \frac{Iload}{D} ) .$$

Thus, the power dissipated by driver power stage 104 would be increased, which would degrade the efficiency of the driver power stage 104. Advantageously, in some embodiments, by operating the driver power stage 104 in three modes of operation, the efficiency of the driver power stage 104 is increased.

In the illustrated example of FIG. 2, when the output voltage is greater than the first threshold, the driver power stage 104 controls the TEC element 102 in buck mode (also referred to as forward mode). For example, as a controller (described below) varies the duty cycle to the switches 202-208 (e.g., in intermediate mode) and the output voltage increases above the first threshold, the controller changes the operational mode of the driver power stage 104 to buck mode. In the example of FIG. 2, the first threshold is chosen based on minimum duty cycle the driver power stage 104 can support in buck mode. For example, the minimum duty cycle that the driver power stage 104 can support in buck mode is 0.1 (e.g., D=0.1).

In the illustrated example of FIG. 2, the first threshold is 10% of the voltage at the supply terminal 212 (e.g., V_{P}=0.1*AVDD). Thus, the driver power stage 104 generates positive voltages in buck mode. By switching the driver power stage 104 to buck mode after crossing a threshold positive voltage, the controller ensures that the driver power stage 104 operates in buck mode over a wider range of positive voltages and limits the range of positive voltages across which the driver power stage 104 operates in intermediate mode. As a result, the efficiency of the driver power stage 104 is increased when producing positive voltages.

FIG. 3 is a schematic diagram of a configuration 300 of the driver power stage 104 of FIG. 2 in forward mode (also referred to as buck mode), according to an embodiment of the present disclosure. In forward mode, the node SW2 is coupled to the TEC element 102 at all times and the node SW1 toggles between the voltage at the supply terminal 212 (e.g., AVDD) and the voltage at the common terminal 106 (e.g., AVSS) in alternating phases. For example, in forward mode, the switch 206 is open, the switch 208 is closed, and the switches 202 and 204 toggle between open and closed responsive to the PHI and PHI2 waveforms, respectively. Thus, the current through the inductor 210 (IL) flows from the node SW1 to the node SW2 (e.g., positive inductor current also referred to as source mode). In forward mode, the average current through the inductor 210 is equal to the current through the TEC element 102 (e.g., IL_{avg}=Iload). In some examples, a switch is open or off when the switch does not conduct current and a switch is closed or on when the switch conducts current.

Returning to FIG. 2, when the output voltage is less than the second threshold, the driver power stage 104 controls the TEC element 102 in inverting buck-boost mode (also referred to as reverse mode). For example, as a controller (described below) varies the duty cycle to the switches 202-208 (e.g., in intermediate mode) and the output voltage decreases below the second threshold, the controller changes the operational mode of the driver power stage 104 to inverting buck-boost mode. In the example of FIG. 2, the second threshold is chosen based on minimum duty cycle the driver power stage 104 can support in inverting buck-boost mode. For example, the minimum duty cycle that the driver power stage 104 can support in inverting buck-boost mode is 0.1 (e.g., D=0.1).

In the illustrated example of FIG. 2, the second threshold is negative 0.5 V (e.g., V_{M}=−0.5 V). Thus, the driver power stage 104 generates negative voltages in inverting buck-boost mode. By switching the driver power stage 104 to inverting buck-boost mode after crossing a threshold negative voltage, the controller ensures that the driver power stage 104 operates in inverting buck-boost mode over a wider range of negative voltages and limits the range of negative voltages across which the driver power stage 104 operates in intermediate mode. As a result, the efficiency of the driver power stage 104 is increased when producing negative voltages.

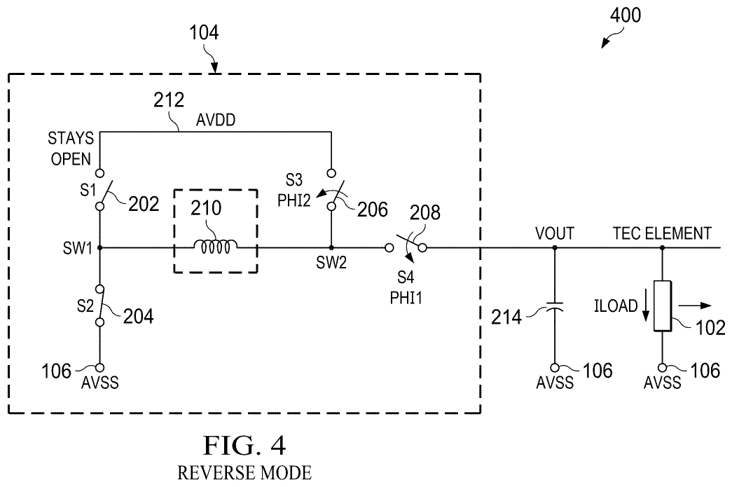

FIG. 4 is a schematic diagram of an example configuration 400 of the driver power stage 104 of FIG. 2 in reverse mode (also referred to as inverting buck-boost mode), according to an embodiment of the present disclosure. In reverse mode, the node SW1 is coupled to the supply terminal 212 at all times and the node SW2 toggles between the voltage at the supply terminal 212 (e.g., AVDD) and the output voltage (VOUT) to the TEC element 102 in alternating phases. For example, in reverse mode, the switch 202 is open, the switch 204 is closed, and the switches 206 and 208 toggle between open and closed responsive to the PHI2 and PHI1 waveforms, respectively. Thus, the current through the inductor 210 (IL) flows from the node SW2 to the node SW1 (e.g., negative inductor current also referred to as sink mode). In reverse mode, the absolute value of the average current through the inductor 210 is greater than the absolute value of the current through the TEC element 102 (e.g., |IL_{avg}|=|Iload|). Additionally, the absolute value of the average current through the inductor 210 in reverse mode is less than the absolute value of the average current through the inductor 210 in intermediate mode (e.g., |IL_{avg}:Reverse Mode|<|IL_{avg}:Intermediate Mode|).

Returning to FIG. 2, when the output voltage is between the first and second thresholds, the driver power stage 104 controls the TEC element 102 in intermediate mode. For example, as a controller (described below) varies the duty cycle to the switches 202-208 (e.g., in buck mode or in inverting buck-boost mode) and the output voltage is less than the first threshold (e.g., V_{P}=0.1*AVDD) and greater than the second threshold (e.g., V_{M}=−0.5 V), the controller changes the operational mode of the driver power stage 104 to intermediate mode. Thus, the driver power stage 104 generates voltages near zero in intermediate mode.

In the illustrated example of FIG. 2, in intermediate mode, the node SW1 toggles between the voltage at the supply terminal 212 (e.g., AVDD) and the voltage at the common terminal 106 (e.g., AVSS) in alternating phases. For example, in intermediate mode, the switches 202 and 204 toggle between open and closed responsive to the PHI1 and PHI2 waveforms, respectively. Additionally, in intermediate mode, the node SW2 toggles between the voltage at the supply terminal 212 (e.g., AVDD) and the output voltage (VOUT) to the TEC element 102 in alternating phases. For example, in intermediate mode, the switches 206 and 208 toggle between open and closed responsive to the PHI2 and PHI1 waveforms, respectively. As described above, in intermediate mode, the driver power stage 104 generates an output voltage of zero volts for a duty cycle of 0.5. For example, the current through the inductor 210 (IL) flows in both directions (e.g., between the nodes SW1 and SW2) depending on the output voltage from the driver power stage 104 and the current through the inductor 210 (IL) can change direction within a switching cycle.

In the illustrated example of FIG. 2, by operating in the three modes described herein, the driver power stage 104 operates with increased efficiency. For example, by operating in the three modes described herein, the efficiency of the driver power stage 104 increases by 8% for peak negative output voltages and by 12% for positive voltages compared to operating in exclusively intermediate mode. Additionally, by operating in the three modes described herein, the peak current through the inductor 210 decreases by 20% compared to operating in exclusively intermediate mode. Thus, because the peak current through the inductor 210 is reduced, an inductor with a smaller saturation current can be used to implement the inductor 210. As such, the size and cost of the inductor 210 can be reduced.

In the illustrated example of FIG. 2, the efficiency of the driver power stage 104 is at a peak level (e.g., 93%) when the driver power stage 104 generates positive output voltages in buck mode. As described above, TEC elements are used in telecommunications applications to control the temperature of laser diodes. While TEC elements can be used to heat or cool a controlled component, TEC elements are primarily used to cool laser diodes in data center applications. Thus, to exploit the peak efficiency of the driver power stage 104, the TEC element 102 is coupled to the output terminal of the driver power stage 104 with negative polarity. With the driver power stage 104 in buck mode and the TEC element 102 coupled with negative polarity, the driver power stage 104 achieves a peak efficiency of 91.9% when sourcing current (e.g., IL>0).

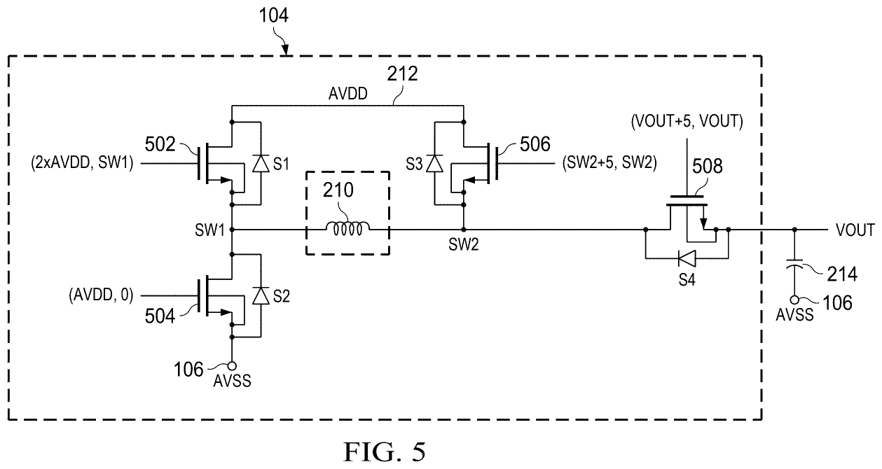

In the illustrated example of FIG. 2, one or more of the switches 202-208 can be implemented by a N-channel metal-oxide semiconductor (NMOS) transistor or a P-channel metal-oxide semiconductor (PMOS) transistor. For example, FIG. 5 is a schematic diagram of the driver power stage 104 of FIG. 2 where the first through fourth switches 202-208 (identified as S1-S4) are implemented by example NMOS transistors 502-508, according to an embodiment of the present disclosure. In the example of FIG. 5, the gate voltage to turn on the NMOS transistor 502 is two times the voltage at the supply terminal 212 and the gate voltage to turn off the NMOS transistor 502 is the voltage at the node SW1 (e.g., 2*AVDD, SW1).

In examples described herein, a transistor has a control terminal, a first current path terminal, and a second current path terminal. For metal-oxide semiconductor (MOS) based devices, the control terminal is referred to as a gate and the first and second current path terminals are referred as a source and a drain, respectively. In operation, a current path can be formed between the two current path terminals of a MOS-based device. For bipolar devices, the control terminal is referred to as a base and the first and second current path terminals are referred to as an emitter and a collector, respectively. In operation, a current path can be formed between the two current path terminals of a bipolar device.

In some examples, a transistor is on when the control voltage of the transistor, such as the gate-to-source voltage (V_{GS}) of an N-channel transistor or the source-to-gate voltage (V_{SG}) of a P-channel transistor, is at a level to cause the transistor to conduct current. For example, a transistor is on when the transistor is in a linear mode of operation or a saturation mode of operation. Conversely, a transistor is off when the control voltage of the transistor, such as the gate-to-source voltage (V_{GS}) of an N-channel transistor or the source-to-gate voltage (V_{SG}) of a P-channel transistor, is at a level to cause the transistor not to conduct current. For example, a transistor is off when the transistor is in a cutoff of operation.

In the illustrated example of FIG. 5, the gate voltage to turn on the NMOS transistor 504 is the voltage at the supply terminal 212 and the gate voltage to turn off the NMOS transistor 504 is zero volts (e.g., AVDD, 0). In the example of FIG. 5, the gate voltage to turn on the NMOS transistor 506 is the voltage at the node SW2 plus five volts and the gate voltage to turn off the NMOS transistor 506 is the voltage at the node SW2 (e.g., SW2+5V, SW2). Also, the gate voltage to turn on the NMOS transistor 508 is the voltage at the output terminal of the driver power stage 104 plus five volts and the gate voltage to turn off the NMOS transistor 508 is the voltage at the output terminal of the driver power stage 104 (e.g., VOUT+5V, VOUT).

In the illustrated example of FIG. 5, an integrated charge pump supplied by the supply terminal 212 (e.g., AVDD) and utilizing high-density on-chip trench capacitors generates the voltage levels to drive the gates of the NMOS transistors 502, 506. As illustrated in FIG. 5, the NMOS transistors 502-508 are N-channel metal-oxide semiconductor field-effect transistors (MOSFETs). Alternatively, the NMOS transistors 502-508 may be N-channel field-effect transistors (FETs), N-channel insulated-gate bipolar transistors (IGBTs), N-channel junction field effect transistors (JFETs), NPN bipolar junction transistors (BJTs), or, with slight modifications, P-channel equivalent devices. The NMOS transistors 502-508 may be depletion mode devices, drain-extended devices, enhancement mode devices, natural transistors, or other type of device structure transistors. Furthermore, the NMOS transistors 502-508 may be implemented in/over a silicon (Si) substrate, a silicon carbide (SiC) substrate, a gallium nitride (GaN) substrate, or a gallium arsenide (GaAs) substrate. To reduce the on-resistance (RON) of the NMOS transistors 502-508, the NMOS transistors 502-508 may be implemented by N-channel laterally-diffused metal-oxide semiconductor (LDMOS) transistors.

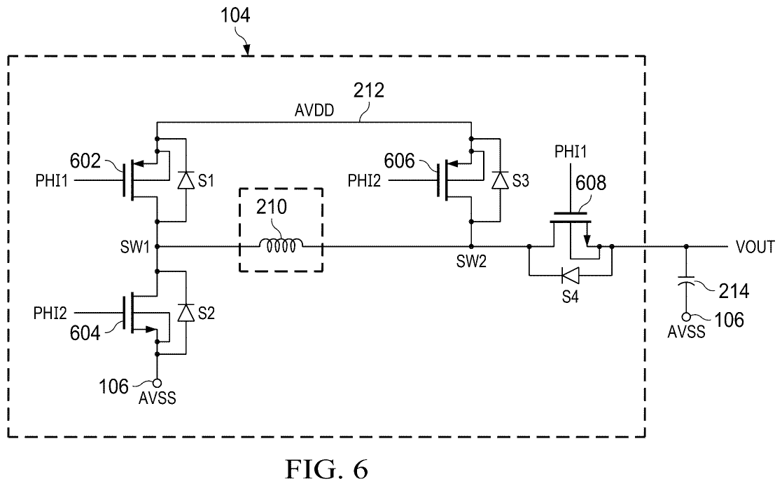

FIG. 6 is a schematic diagram of the driver power stage 104 of FIG. 2 where the second and fourth switches 204, 208 are implemented by example NMOS transistors 604, 608 and the first and third switches 202, 206 are implemented by example PMOS transistors 602, 606, according to an embodiment of the present disclosure. In the example of FIG. 6, a charge pump is not utilized to drive the gate of the high-side transistors (e.g., the PMOS transistors 602, 606). As such, the design complexity of the driver power stage 104 is reduced. For purposes of simplicity, the gate voltages to turn on the NMOS transistors 604, 608 and the PMOS transistors 602, 606 are not described herein. By implementing the switch 208 with a single NMOS transistor (e.g., the NMOS transistor 608), the switch 208 consumes three times less area than implementing the switch 208 with a transmission gate.

As illustrated in FIG. 6, the NMOS transistors 604, 608 are N-channel MOSFETs. Alternatively, the NMOS transistors 604, 608 may be N-channel FETs, N-channel IGBTs, N-channel JFETs, NPN BJTs, or, with slight modifications, P-channel equivalent devices. In the example of FIG. 6, the PMOS transistors 602, 606 are P-channel MOSFETs (e.g., drain-extended PMOS transistors). Alternatively, the PMOS transistors 602, 606 may be P-channel FETs, P-channel IGBTs, P-channel JFETs, PNP BJTs, or, with slight modifications, N-channel equivalent devices. The NMOS transistors 604, 608 and the PMOS transistors 602, 606 may be depletion mode devices, drain-extended devices, enhancement mode devices, natural transistors, or other type of device structure transistors. Furthermore, the NMOS transistors 604, 608 and the PMOS transistors 602, 606 may be implemented in/over a Si substate, a SiC substrate, a GaN substrate, or a GaAs substrate.

Table 1 below illustrates different options to implement the switches 202-208 (identified as S1-S4) as NMOS and PMOS transistors in FIGS. 5 and 6. For example, the different NMOS and PMOS transistor options in Table 1 have on-resistance (RON) values that facilitate meeting a target efficiency of 90% at peak current through the inductor 210. In the example of FIG. 2, the current through the inductor 210 reaches a peak value in inverting buck-boost mode while generating peak negative voltages.

TABLE 1

| | | | | Gate |
|---|---|---|---|---|
| | RON | | | Capacitance |
| Switch | (mΩ) | Choice of Switch | Area (mm²) | (pF) |
| S1 | ~50 | 5 V Power Switch | ~0.3 | ~200 |
| S1 | ~50 | 7 V Isolation LDMOS | ~0.1 | ~25 |
| S2 | ~15 | 7 V Isolation LDMOS | ~0.5 | ~80 |
| S4 | ~15 | 11 V Isolation LDMOS | ~0.7 | ~150 |
| S3 | ~15 | 9 V Power Switch | ~3 | ~1,500 |
| S3 | ~15 | 11 V Isolation LDMOS | ~0.7 | ~150 |

As illustrated in Table 1, implementing the driver power stage 104 with the NMOS transistors 502-508 (e.g., rows 3-5 and 7) consumes less area than implementing the driver power stage 104 with the NMOS transistors 604, 608 (e.g., rows 4 and 5, respectively) and the PMOS transistors 602, 606 (e.g., rows 2 and 6, respectively). Additionally, implementing the driver power stage 104 with the NMOS transistors 502-508 (e.g., rows 3-5 and 7) facilitates a 25% reduction in total chip area consumption compared to other approaches.

As described above, the driver power stage 104 drives the TEC element 102 in a single-ended manner with one end of the TEC element 102 grounded. The driver power stage 104 can drive both positive voltages and negative voltages utilizing a single unipolar supply, a single power inductor (e.g., the inductor 210), and a single capacitor (e.g., the capacitor 214) which reduces the occupied board area of the TEC system and reduces system cost. The four switch topology of the driver power stage 104 can be configured in multiple switching modes (e.g., buck mode, inverting buck-boost mode, and intermediate mode) by changing the switching sequence of the four switches as described herein.

As described above, the driver power stage 104 actively changes between different operational modes depending on whether the output voltage from the driver power stage 104 is greater than the first threshold, less than the second threshold, or between the first and second thresholds. For example, when the output voltage is greater than the first threshold, the driver power stage 104 operates in buck mode to generate positive voltages. When the output voltage is less than the second threshold, the driver power stage 104 operates in inverting buck-boost mode to generate negative voltages. When the output voltage is between the first and second thresholds, the driver power stage 104 operates in intermediate mode to generate voltages near zero for zero-crossings. For example, the two-phase switching sequence of the driver power stage 104 in intermediate mode ensures that the zero-crossing of the driver power stage 104 occurs around a duty cycle of 0.5 which provides glitch-free zero-crossing and a simplified overall feedback loop to ensure very high temperature stability (e.g., within <5 m° C. of a target temperature).

Example multi-mode operation described herein improves the overall efficiency of power delivery to the TEC element 102. For example, multi-mode operation described herein increases efficiency for mid-level and higher power delivery. The efficiency of power delivery to the TEC element 102 can be further improved by toggling the polarity of the TEC element 102 so that the driver power stage 104 drives the TEC element 102 in the highest efficiency mode (e.g., buck mode) during the majority of operation. Additionally, example multi-mode operation described herein reduces the steady-state peak current through the inductor 210 and permits the use of an inductor with smaller saturation current. As such, the footprint of the inductor 210 can be reduced.

In the illustrated example of FIG. 2, to ensure proper operation of the driver power stage 104, a controller (described below) monitors for undercurrent (UI) events during discharging phases in addition to monitoring for overcurrent (OI) events during charging phases. For example, if a short circuit presents at the output terminal of the driver power stage 104 during buck mode operation and the current through the inductor 210 (IL) is only monitored for OI events during charging phases (e.g., when the switch 202 is closed and the switch 204 is open), then it is possible for the current through the inductor 210 to build up in the subsequent phases. If the short circuit condition persists, the current through the inductor 210 (IL) can run away.

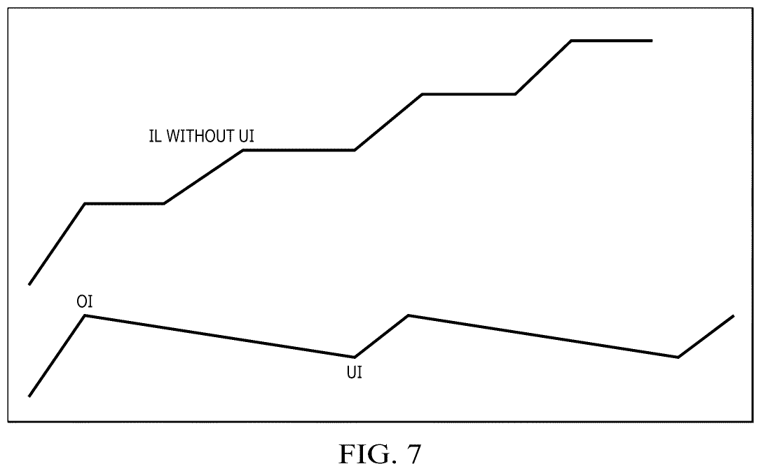

FIG. 7 is a timing diagram depicting possible inductor current in the driver power stage 104 of FIG. 2. As illustrated in FIG. 7, if the current through the inductor 210 is only monitored for OI events during charging phases, then the current through the inductor 210 can build up during subsequent phases and run away. However, if the current through the inductor 210 is monitored for UI events during discharging phases in addition to monitoring for OI events during charging phases, then the current through the inductor 210 is maintained at a target average value. For example, once the current through the inductor 210 (IL) is lower than a UI limit during a discharging phase, the driver power stage 104 transitions back to a charging phase. Additionally, once the current through the inductor 210 (IL) is greater than an OI limit during a charging phase, the driver power stage 104 transitions back to a discharging phase. As such, the current through the inductor 210 does not run away, even in short circuit conditions.

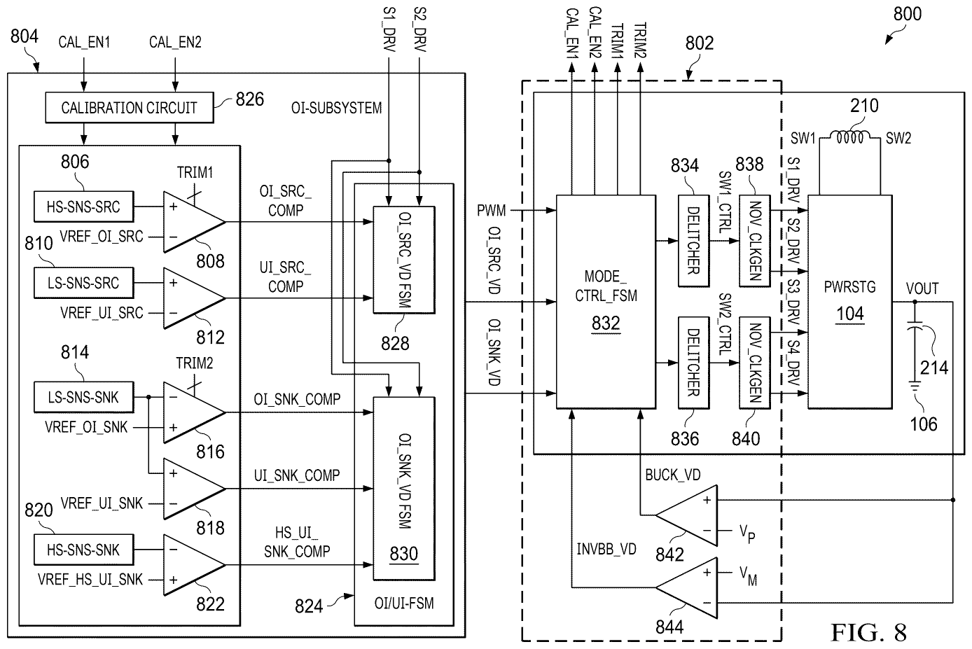

FIG. 8 is a block diagram of system 800 including controller 802 for the driver power stage 104 of FIG. 2 and OI current sensor subsystem 804 for the driver power stage 104, according to an embodiment of the present disclosure. In the example of FIG. 8, there are two possible OI events that can occur, one during source mode (e.g., when the current through the inductor 210 is positive) and one during sink mode (e.g., when the current through the inductor 210 is negative). To monitor for both OI events, OI current sensor subsystem 804 includes high-side source mode sensor 806 (identified as HS-SNS-SRC), high-side source mode OI comparator 808, low-side source mode sensor 810 (identified as LS-SNS-SRC), and low-side source mode UI comparator 812. The OI current sensor subsystem 804 of FIG. 8 also includes low-side sink mode sensor 814 (identified as LS-SNS-SNK), low-side sink mode OI comparator 816, low-side sink mode UI comparator 818, high-side sink mode sensor 820 (identified as HS-SNS-SNK), and high-side sink mode UI comparator 822.

In the illustrated example of FIG. 8, the OI current sensor subsystem 804 includes OI/UI state machine 824 (identified as OI/UI-FSM) and calibration circuit 826. In the example of FIG. 8, the OI/UI state machine 824 includes source mode state machine 828 (identified as OI_SRC_VD FSM) and sink mode state machine 830 (identified as OI_SNK_VD FSM). Additionally, the controller 802 of FIG. 8 includes mode control state machine 832 (identified as MODE_CTRL_FSM), deglitching circuits 834, 836, and non-overlapping clock generation circuits 838, 840. In the example of FIG. 8, the controller 802 also includes buck mode comparator 842 and inverting buck-boost mode comparator 844.

In the illustrated example of FIG. 8, the OI current sensor subsystem 804 supports the three modes of operation of the driver power stage 104 described herein. In the example of FIG. 8, each of the high-side source mode sensor 806, the low-side source mode sensor 810, the low-side sink mode sensor 814, and the high-side sink mode sensor 820 is a current sensing circuit that includes a replica transistor (e.g., a replica FET) to sense the current through the inductor 210 in a lossless manner. Depending on the current mode of the driver power stage 104, different ones of the high-side source mode sensor 806, the low-side source mode sensor 810, the low-side sink mode sensor 814, and the high-side sink mode sensor 820 sense current through the inductor 210.

In the illustrated example of FIG. 8, the high-side source mode sensor 806, the low-side source mode sensor 810, the low-side sink mode sensor 814, and the high-side sink mode sensor 820 are associated with the switches coupled to the node SW1 (e.g., the switches 202, 204). By monitoring the switches coupled to the node SW1 (e.g., the switches 202, 204), the OI current sensor subsystem 804 reduces design constraints. For example, if sensors were implemented to monitor the switches coupled to the node SW2 (e.g., the switches 206, 208), then the sensors would receive negative voltages associated with the node SW2 and would need to use high voltage transistors that would further complicate design.

In the illustrated example of FIG. 8, when the driver power stage 104 is in source mode (e.g., when the current through the inductor 210 is positive), the high-side source mode sensor 806 senses the current through the switch 202. In the example of FIG. 8, the high-side source mode sensor 806 provides a voltage that is representative of the sensed current through the switch 202 and has a direct relationship to the current through the switch 202. For example, as the current through the switch 202 increases, the voltage provided by the high-side source mode sensor 806 increases. Additionally, as the current through the switch 202 decreases, the voltage provided by the high-side source mode sensor 806 decreases.

As such, the high-side source mode OI comparator 808 can monitor for an OI event when the driver power stage 104 is in source mode (both during buck mode and intermediate mode operation). For example, the high-side source mode OI comparator 808 compares a voltage representative of the sensed current from the high-side source mode sensor 806 to a source mode OI reference voltage (identified as VREF_OI_SRC). In the example of FIG. 8, the source mode OI reference voltage is a programmable voltage and corresponds to or is proportional to a source mode OI limit (also referred to as a source mode OI threshold) between 2.5 amps (A) and 4.8 A.

In the illustrated example of FIG. 8, when the driver power stage 104 is in source mode, the low-side source mode sensor 810 senses the current through the switch 204. In the example of FIG. 8, the low-side source mode sensor 810 provides a voltage that is representative of the sensed current through the switch 204 and has an indirect relationship to the current through the switch 204. For example, as the current through the switch 204 increases, the voltage provided by the low-side source mode sensor 810 decreases. Additionally, as the current through the switch 204 decreases, the voltage provided by the low-side source mode sensor 810 increases.

As such, the low-side source mode UI comparator 812 can monitor for a UI event when the driver power stage 104 is in source mode (both during buck mode and intermediate mode operation). For example, the low-side source mode UI comparator 812 compares a voltage representative of the sensed current from the low-side source mode sensor 810 to a source mode UI reference voltage (identified as VREF_UI_SRC). In the example of FIG. 8, the source mode UI reference voltage is a programmable voltage and corresponds to or is proportional to a source mode UI limit (also referred to as a source mode UI threshold) of 750 milliamps (mA) less than the source mode OI limit.

In the illustrated example of FIG. 8, when the driver power stage 104 is in sink mode (e.g., when the current through the inductor 210 is negative), the low-side sink mode sensor 814 senses the current through the switch 204. In the example of FIG. 8, the low-side sink mode sensor 814 provides a voltage that is representative of the sensed current through the switch 204 and has an indirect relationship to the current through the switch 204. For example, as the current through the switch 204 increases, the voltage provided by the low-side sink mode sensor 814 decreases. Additionally, as the current through the switch 204 decreases, the voltage provided by the low-side sink mode sensor 814 increases.

As such, the low-side sink mode OI comparator 816 and the low-side sink mode UI comparator 818 can monitor for an OI event and a UI event, respectively, when the driver power stage 104 is in sink mode (both during inverting buck-boost mode and intermediate mode operation). For example, the low-side sink mode OI comparator 816 compares a voltage representative of the sensed current from the low-side sink mode sensor 814 to a sink mode OI reference voltage (identified as VREF_OI_SNK). In the example of FIG. 8, the sink mode OI reference voltage is a programmable voltage and corresponds to or is proportional to a sink mode OI limit (also referred to as a sink mode OI threshold) between −2.5 A and −4.8 A. Additionally, the low-side sink mode UI comparator 818 compares a voltage representative of the sensed current from the low-side sink mode sensor 814 to a low-side sink mode UI reference voltage (identified as VREF_UI_SNK). In the example of FIG. 8, the low-side sink mode UI reference voltage is a programmable voltage and corresponds to or is proportional to a low-side sink mode UI limit (also referred to as a low-side sink mode UI threshold) of 750 mA higher than the sink mode OI limit.

In the illustrated example of FIG. 8, when the driver power stage 104 is in sink mode, the high-side sink mode sensor 820 senses the current through the switch 202. In the example of FIG. 8, the high-side sink mode sensor 820 provides a voltage that is representative of the sensed current through the switch 202 and has a direct relationship to the current through the switch 202. For example, as the current through the switch 202 increases, the voltage provided by the high-side sink mode sensor 820 increases. Additionally, as the current through the switch 202 decreases, the voltage provided by the high-side sink mode sensor 820 decreases.

As such, the high-side sink mode UI comparator 822 can monitor for a UI event when the driver power stage 104 is in sink mode (both during inverting buck-boost mode and intermediate mode operation). For example, the high-side sink mode UI comparator 822 compares a voltage representative of the sensed current from the high-side sink mode sensor 820 to a high-side sink mode UI reference voltage (identified as VREF_HS_UI_SNK). In the example of FIG. 8, the high-side sink mode UI reference voltage is a programmable voltage and corresponds to or is proportional to a high-side sink mode UI limit (also referred to as a high-side sink mode UI threshold) of 750 mA higher than the sink mode OI limit.

In the illustrated example of FIG. 8, based on the comparisons, the high-side source mode OI comparator 808, the low-side source mode UI comparator 812, the low-side sink mode OI comparator 816, the low-side sink mode UI comparator 818, and the high-side sink mode UI comparator 822 provide signals to the OI/UI state machine 824 indicative of whether a source mode OI event, a source mode UI event, a sink mode OI event, and/or a sink mode UI event was detected. For example, responsive to the output of the high-side source mode sensor 806 and the source mode OI reference voltage, the high-side source mode OI comparator 808 provides an OI source mode signal (identified as OI_SRC_COMP) to the source mode state machine 828. In the example of FIG. 8, responsive to the output of the high-side source mode sensor 806 exceeding the source mode OI reference voltage (e.g., the absolute value of the current through the switch 202 exceeding the source mode OI threshold), the OI source mode signal indicates that a source mode OI event was detected.

In the illustrated example of FIG. 8, responsive to the output of the low-side source mode sensor 810 and the source mode UI reference voltage, the low-side source mode UI comparator 812 provides a UI source mode signal (identified as UI_SRC_COMP) to the source mode state machine 828. For example, responsive to the output of the low-side source mode sensor 810 exceeding the source mode UI reference voltage (e.g., the absolute value of the current through the switch 204 being less than (e.g., dropping below) the source mode UI threshold), the UI source mode signal indicates that a source mode UI event was detected. In the example of FIG. 8, the low-side sink mode OI comparator 816 provides an OI sink mode signal (identified as OI_SNK_COMP) to the sink mode state machine 830 responsive to the output of the low-side sink mode sensor 814 and the sink mode OI reference voltage. For example, responsive to the output of the low-side sink mode sensor 814 being less than (e.g., dropping below) the sink mode OI reference voltage (e.g., the absolute value of the current through the switch 204 exceeding the sink mode OI threshold), the OI sink mode signal indicates that a sink mode OI event was detected.

In the illustrated example of FIG. 8, the low-side sink mode UI comparator 818 provides a low-side UI sink mode signal (identified as UI_SNK_COMP) to the sink mode state machine 830 responsive to the output of the low-side sink mode sensor 814 and the low-side sink mode UI reference voltage. For example, responsive to the output of the low-side sink mode sensor 814 exceeding the low-side sink mode UI reference voltage (e.g., the absolute value of the current through the switch 204 being less than (e.g., dropping below) the low-side sink mode UI threshold), the low-side UI sink mode signal indicates that a low-side sink mode UI event was detected. In the example of FIG. 8, responsive to the output of the high-side sink mode sensor 820 and the high-side sink mode UI reference voltage, the high-side sink mode UI comparator 822 provides a high-side UI sink mode signal (identified as HS_UI_SNK_COMP) to the sink mode state machine 830. For example, responsive to the output of the high-side sink mode sensor 820 being less than (e.g., dropping below) the high-side sink mode UI reference voltage (e.g., the absolute value of the current through the switch 202 being less than (e.g., dropping below) the high-side sink mode UI threshold), the high-side UI sink mode signal indicates that a high-side sink mode UI event was detected.

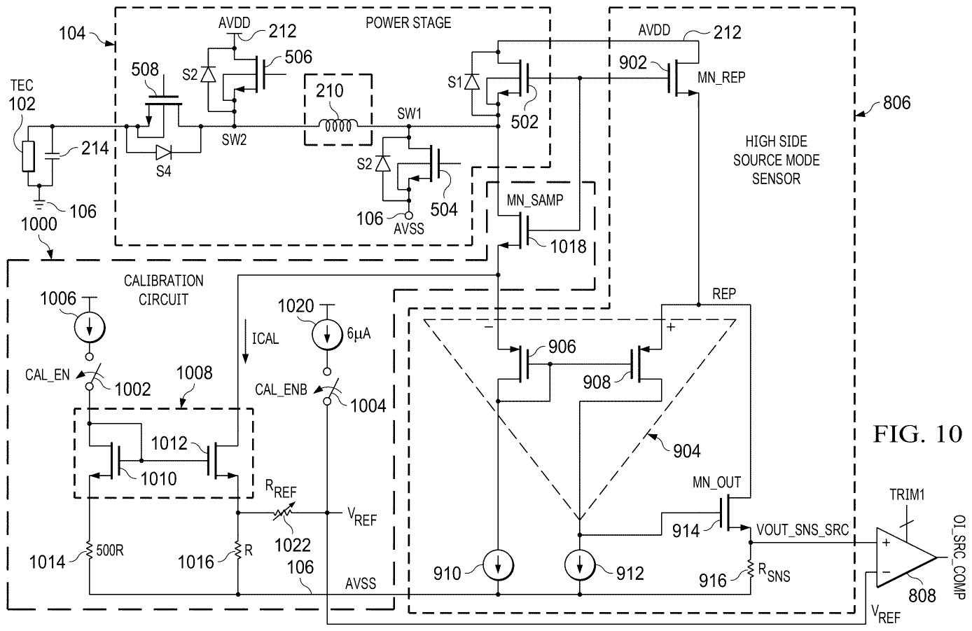

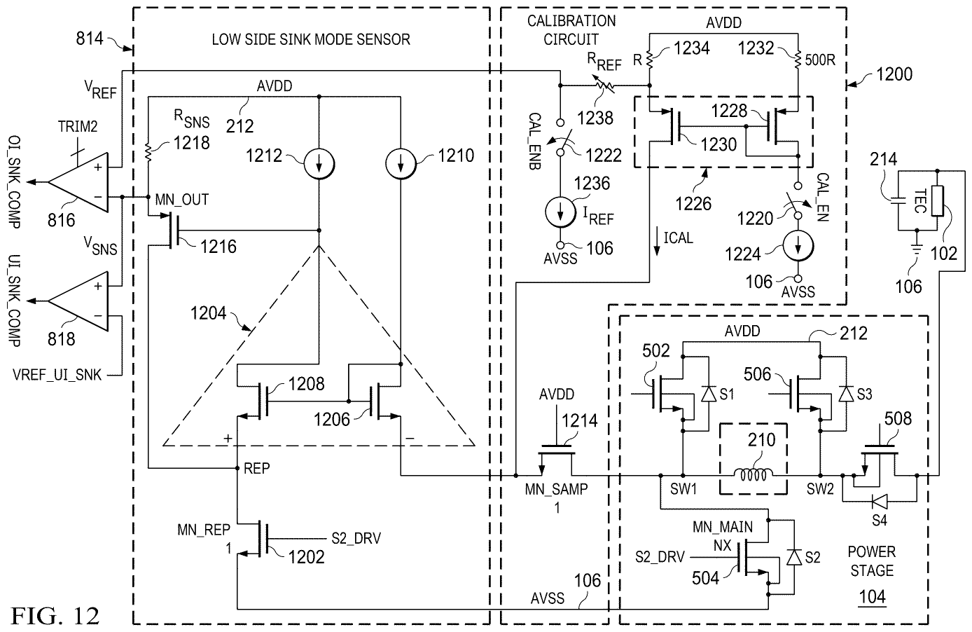

In some examples, the calibration circuit 826 can be utilized to facilitate calibration of the high-side source mode OI comparator 808 and the low-side sink mode OI comparator 816. For example, at startup of the driver power stage 104, the mode control state machine 832 provides calibration enable signals (identified as CAL_EN1 and CAL_EN2) to enable respective calibration circuits for the high-side source mode OI comparator 808 and the low-side sink mode OI comparator 816. Based on the calibration, the mode control state machine 832 provides trim signals (identified as TRIM1 and TRIM2) to calibrate the high-side source mode OI comparator 808 and the low-side sink mode OI comparator 816, respectively. An example implementation of a calibration circuit for the high-side source mode OI comparator 808 is further illustrated and described, e.g., in FIG. 10. An example implementation of a calibration circuit for the low-side sink mode OI comparator 816 is further illustrated and described, e.g., in FIG. 12.

In the illustrated example of FIG. 8, the source mode state machine 828 receives the OI source mode signal and the UI source mode signal. Additionally, the source mode state machine 828 receives drive signals for the switches 202, 204 (identified as S1_DRV and S2_DRV, respectively). In the example of FIG. 8, the source mode state machine 828 deglitches the drive signals. Responsive to the deglitched drive signals, the OI source mode signal, and the UI source mode signal, the source mode state machine 828 provides a source mode OI detection signal (identified as OI_SRC_VD) to the mode control state machine 832.

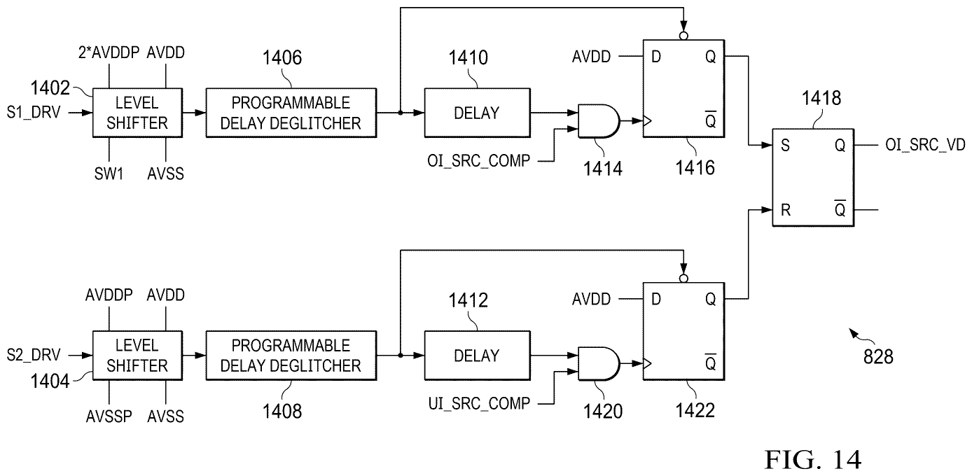

For example, responsive to the OI source mode signal indicating that a source mode OI event was detected and a close value on the drive signal for the switch 202 (e.g., indicating the switch 202 is to be closed), the source mode state machine 828 sets the source mode OI detection signal to indicate that a source mode OI event was detected. Responsive to the UI source mode signal indicating that a source mode UI event was detected and a close value on the drive signal for the switch 204 (e.g., indicating the switch 204 is to be closed), the source mode state machine 828 resets the source mode OI detection signal to indicate that the detected source mode OI event has cleared. An example implementation of source mode state machine 828 is further illustrated and described, e.g., in FIG. 14.

In the illustrated example of FIG. 8, the sink mode state machine 830 receives the OI sink mode signal, the low-side UI sink mode signal, and the high-side UI sink mode signal. Additionally, the sink mode state machine 830 receives the drive signals for the switches 202, 204. In the example of FIG. 8, the sink mode state machine 830 deglitches the drive signals. Responsive to the deglitched drive signals, the OI sink mode signal, the low-side UI sink mode signal, and the high-side UI sink mode signal, the sink mode state machine 830 provides a sink mode OI detection signal (identified as OI_SNK_VD) to the mode control state machine 832.

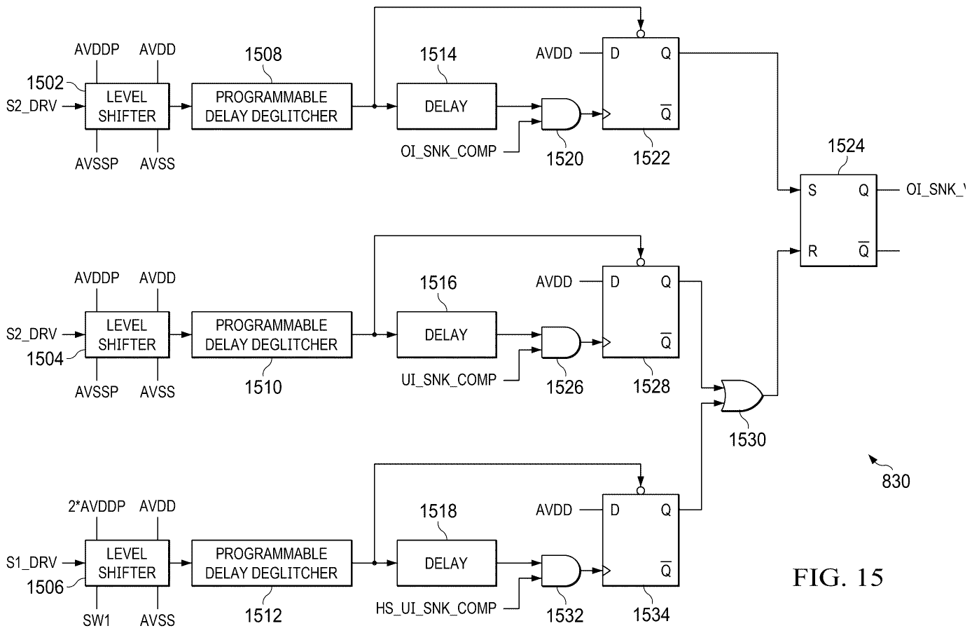

For example, responsive to the OI sink mode signal indicating that a sink mode OI event was detected and a close value on the drive signal for the switch 204 (e.g., indicating the switch 204 is to be closed), the sink mode state machine 830 sets the sink mode OI detection signal to indicate that a sink mode OI event was detected. Responsive to the low-side UI sink mode signal indicating that a low-side sink mode UI event was detected and a close value on the drive signal for the switch 204 (e.g., indicating the switch 204 is to be closed), the sink mode state machine 830 resets the sink mode OI detection signal to indicate that the detected sink mode OI event has cleared. Additionally or alternatively, responsive to the high-side UI sink mode signal indicating that a high-side sink mode UI event was detected and a close value on the drive signal for the switch 202 (e.g., indicating the switch 202 is to be closed), the sink mode state machine 830 resets the sink mode OI detection signal to indicate that the detected sink mode OI event has cleared. An example implementation of the sink mode state machine 830 is further illustrated and described, e.g., in FIG. 15.

In the illustrated example of FIG. 8, during normal operation, the mode control state machine 832 controls the driver power stage 104 in one of the three modes of operation described herein responsive to a pulse width modulation (PWM) signal. For example, the PWM signal is generated based on a comparison between a target temperature of a controlled component (such as a laser diode) and a temperature measurement from a thermistor in circuit with or in proximity to the controlled component. Based on the comparison, a control circuit (not illustrated) generates the PWM signal to bring the measured temperature of the controlled component to the target temperature. For example, the target temperature ranges between negative 40° C. and 125° C.

In the illustrated example of FIG. 8, responsive to the PWM signal, the mode control state machine 832 generates control signals for the nodes SW1 and SW2 (identified as SW1_CTRL and SW2_CTRL, respectively). In the example of FIG. 8, the control signal for the node SW1 indicates whether the node SW1 is to be coupled to the supply terminal 212 or the common terminal 106. Additionally, the control signal for the node SW2 indicates whether the node SW2 is to be coupled to the supply terminal 212 or the output terminal of the driver power stage 104. In the example of FIG. 8, the deglitching circuits 834, 836 deglitch the control signals and the non-overlapping clock generation circuits 838, 840 generate drive signals for the switches 202-208. For example, the non-overlapping clock generation circuit 838 generates the drive signals for the switch 202 and the switch 204 (identified as S1_DRV and S2_DRV, respectively). Additionally, the non-overlapping clock generation circuit 830 generates drive signals for the switch 206 and the switch 208 (identified as S3_DRV and S4_DRV, respectively).

In the illustrated example of FIG. 8, the drive signals for the switches 202-208 control the mode of operation of the driver power stage 104. For example, when the first and second drive signals (e.g., S1_DRV, S2_DRV) control the switches 202, 204 to operate in alternate phases and the third and fourth drive signals (e.g., S3_DRV, S4_DRV) control the switches 206, 208 to be open and closed, respectively, the driver power stage 104 is in the buck mode of operation. In such an example, the first and second drive signals (e.g., S1_DRV, S2_DRV) correspond to the PHI1 and PHI2 waveforms, respectively. Additionally, when the first and second drive signals (e.g., S1_DRV, S2_DRV) control the switches 202, 204 to be open and closed, respectively, and the third and fourth drive signals (e.g., S3_DRV, S4_DRV) control the switches 206, 208 to operate in alternate phases, the driver power stage 104 is in the inverting buck-boost mode of operation. In such an example, the third and fourth drive signals (e.g., S3_DRV, S4_DRV) correspond to the PHI2 and PHI1 waveforms, respectively.

In the illustrated example of FIG. 8, when the first and fourth drive signals (e.g., S1_DRV, S4_DRV) control the switches 202, 208 to operate in alternating phases according to a first clock signal (e.g., the PHI1 waveform), and the second and third drive signals (e.g., S2_DRV, S3_DRV) control the switches 204, 206 to operate in alternate phases according to a second clock signal (e.g., the PHI2 waveform), the driver power stage 104 is in the intermediate mode of operation. For example, the first and second clock signals have fixed frequencies, and the second clock signal is non-overlapping with respect to the first clock signal to prevent shoot through as described above. To control which mode of operation the driver power stage 104 is in, the mode control state machine 832 monitors the buck mode comparator 842 and the inverting buck-boost mode comparator 844.

In the illustrated example of FIG. 8, the buck mode comparator 842 and the inverting buck-boost mode comparator 844 monitor the output voltage (VOUT). For example, the buck mode comparator 842 compares the output voltage to the first threshold (e.g., V_{P}). Responsive to the output voltage and the first threshold, the buck mode comparator 842 provides a buck mode control signal (identified as BUCK_VD) to the mode control state machine 832. Additionally, the inverting buck-boost mode comparator 844 compares the output voltage to the second threshold (e.g., V_{M}). Responsive to the output voltage and the second threshold, the inverting buck-boost mode comparator 844 provides an inverting buck-boost mode control signal (identified as INVBB_VD) to the mode control state machine 832. Responsive to the buck mode control signal and the inverting buck-boost mode control signal, the mode control state machine 832 transitions the driver power stage 104 to one of the three modes of operation described herein.

For example, responsive to the output voltage exceeding the first threshold, the buck mode control signal and the inverting buck-boost mode control signal indicate to the mode control state machine 832 that the driver power stage 104 is to be transitioned to buck mode. Responsive to the output voltage being less than (e.g., dropping below) the second threshold, the buck mode control signal and the inverting buck-boost mode control signal indicate to the mode control state machine 832 that the driver power stage 104 is to be transitioned to inverting buck-boost mode. Additionally, responsive to the output voltage being between the first and second thresholds, the buck mode control signal and the inverting buck-boost mode control signal indicate to the mode control state machine 832 that the driver power stage 104 is to be transitioned to intermediate mode.

As described above, the PWM signal is generated to bring the measured temperature of a controlled component (e.g., a laser diode) to a target temperature. Additionally, the mode control state machine 832 generates the drive signals for the switches 202-208 based on the PWM signal to adjust how much heat the TEC element 102 is sourcing or sinking. Thus, in each mode of operation the mode control state machine 832 adjusts the duty cycles of the toggling switches (e.g., the switches 202, 204 in buck mode, the switches 206, 208 in inverting buck-boost mode, or the switches 202-208 in intermediate mode) to regulate the output voltage of the driver power stage 104 to bring the measured temperature to the target temperature. For example, in intermediate mode (e.g., when the output voltage is between the first and second thresholds), the mode control state machine 832 regulates the output voltage from the driver power stage 104 by adjusting the duty cycle of one or more of the first through fourth drive signals to the switches 202-208.

In the illustrated example of FIG. 8, responsive to the source mode OI detection signal and/or the sink mode OI detection signal indicating that an OI event was detected, the mode control state machine 832 provides control signals for the nodes SW1 and SW2 to transition the driver power stage 104 to a safe state. For example, in a safe state, the driver power stage 104 reliably discharges the inductor 210 to reduce the current through the inductor 210 to a lower level.

TABLE 2

| | Switches | Switches | |
|---|---|---|---|
| | Turned | Turned | |
| Mode of | On During | On For | |
| Operation | Charge Phase | Corrective Action | Current Mode |
| Buck | S1, S4 | S2, S4 | Source Mode |
| Intermediate | S1, S4 | S2, S4 | Source Mode |
| Intermediate | S2, S3 | S1, S4 | Sink Mode |
| Inverting | S2, S3 | S2, S4 | Sink Mode |
| Buck-boost | | | |

As illustrated in Table 2, responsive to the driver power stage 104 operating in buck mode and the source mode OI detection signal indicating that a source mode OI event was detected, the mode control state machine 832 provides control signals for the nodes SW1 and SW2 to couple the node SW1 to the common terminal 106 and to couple the node SW2 to the output terminal of the driver power stage 104. As described above, the source mode OI detection signal indicates that a source mode OI event was detected when the absolute value of the inductor current is higher than the source mode OI threshold. In the example of FIG. 8, to couple the node SW1 to the common terminal 106 and the node SW2 to the output terminal of the driver power stage 104, the mode control state machine 832 provides control signals to open the switch 202, to close the switch 204, to open the switch 206, and to close the switch 208. As such, the inductor 210 can start a discharging phase to bring the current through the inductor 210 to a target level.

During the discharging phase, the switch 202 remains open, the switch 204 remains closed, the switch 206 remains open, and the switch 208 remains closed. In the example of FIG. 8, responsive to the source mode OI detection signal indicating that the detected source mode OI event has cleared (e.g., the absolute value of the inductor current being lower than the source mode UI threshold), the mode control state machine 832 restarts operation of the switches 202-208 in buck mode to exit the discharging phase of the inductor 210. As illustrated in Table 2, the mode control state machine 832 operates similarly responsive to the driver power stage 104 operating in intermediate mode and the source mode OI detection signal indicating that a source mode OI event was detected.

Additionally, as illustrated in Table 2, responsive to the driver power stage 104 operating in intermediate mode and the sink mode OI detection signal indicating that a sink mode OI event was detected, the mode control state machine 832 provides control signals for the nodes SW1 and SW2 to couple the node SW1 to the supply terminal 212 and to couple the node SW2 to the output terminal of the driver power stage 104. As described above, the sink mode OI detection signal indicates that a sink mode OI event was detected when the absolute value of the inductor current is higher than the sink mode OI threshold. In the example of FIG. 8, to couple the node SW1 to the supply terminal 212 and the node SW2 to the output terminal of the driver power stage 104, the mode control state machine 832 provides control signals to close the switch 202, to open the switch 204, to open the switch 206, and to close the switch 208.

As such, the inductor 210 can start a discharging phase to bring the current through the inductor 210 to a target level. During the discharging phase, the switch 202 remains closed, the switch 204 remains open, the switch 206 remains open, and the switch 208 remains closed. In the example of FIG. 8, responsive to the sink mode OI detection signal indicating that the detected sink mode OI event has cleared, the mode control state machine 832 restarts operation of the switches 202-208 in intermediate mode to exit the discharging phase of the inductor 210. For intermediate mode, the sink mode OI detection signal indicates that the detected sink mode OI event has cleared when the absolute value of the inductor current is lower than the high-side sink mode UI threshold.

As illustrated in Table 2, responsive to the driver power stage 104 operating in inverting buck-boost mode and the sink mode OI detection signal indicating that a sink mode OI event was detected, the mode control state machine 832 provides control signals for the nodes SW1 and SW2 to couple the node SW1 to the common terminal 106 and to couple the node SW2 to the output terminal of the driver power stage 104. As described above, the sink mode OI detection signal indicates that a sink mode OI event was detected when the absolute value of the inductor current is higher than the sink mode OI threshold. In the example of FIG. 8, to couple the node SW1 to the common terminal 106 and the node SW2 to the output terminal of the driver power stage 104, the mode control state machine 832 provides control signals to open the switch 202, to close the switch 204, to open the switch 206, and to close the switch 208.

As such, the inductor 210 can start a discharging phase to bring the current through the inductor 210 to a target level. During the discharging phase, the switch 202 remains open, the switch 204 remains closed, the switch 206 remains open, and the switch 208 remains closed. In the example of FIG. 8, responsive to the sink mode OI detection signal indicating that the detected sink mode OI event has cleared, the mode control state machine 832 restarts operation of the switches 202-208 in inverting buck-boost mode to exit the discharging phase of the inductor 210. For inverting buck-boost mode, the sink mode OI detection signal indicates that the detected sink mode OI event has cleared when the absolute value of the inductor current is lower than the low-side sink mode UI threshold.

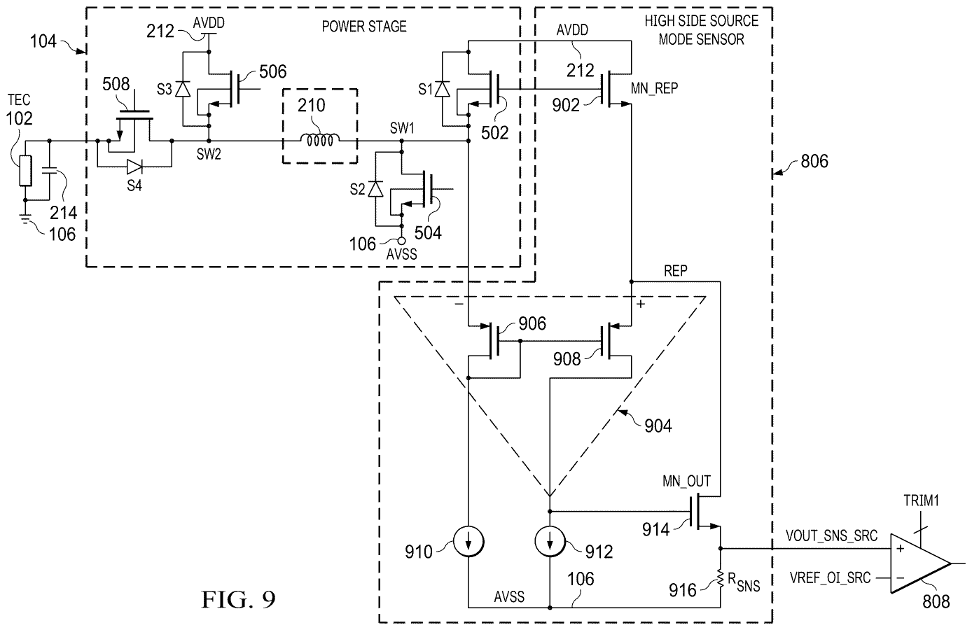

FIG. 9 is a schematic diagram of the high-side source mode sensor 806 of FIG. 8, according to an embodiment of the present disclosure. As described above, current through the inductor 210 flows from the node SW1 to the node SW2 in source mode and the high-side source mode sensor 806 senses the current through the switch 202 to monitor for a source mode OI event. In the example of FIG. 9, the high-side source mode sensor 806 is illustrated relative to the driver power stage 104 of FIG. 5. For example, the high-side source mode sensor 806 includes an example replica transistor 902 (identified as MN_REP) that is used in parallel with the NMOS transistor 502 to monitor the current through the NMOS transistor 502. For example, the controller 802 applies the drive signal for the NMOS transistor 502 to the gates of the NMOS transistor 502 and the replica transistor 902. In the example of FIG. 9, the replica transistor 902 is

$$\frac{1}{N}$$

times the size of the NMOS transistor 502.

In the illustrated example of FIG. 9, the high-side source mode sensor 806 also includes operational amplifier (op-amp) 904 that is implemented in the current domain to achieve a quicker response time for sensing (e.g., determining) the current through the NMOS transistor 502. In the example of FIG. 9, the op-amp 904 is implemented by a current input amplifier including a PMOS input pair of example transistors 906, 908. For example, the source of the transistor 906 corresponds to the inverting input of the op-amp 904 and the source of the transistor 908 corresponds to the non-inverting input of the op-amp 904. Additionally, the drain of the transistor 908 corresponds to the output of the op-amp 904. In the example of FIG. 9, the transistor 906 is biased by a first example current source 910 and the transistor 908 is biased by a second example current source 912.

In the illustrated example of FIG. 9, responsive to the feedback action of the op-amp 904, the op-amp 904 forces the voltage at the replica node (identified as REP) to be equal to or within an acceptable range of the voltage at the node SW1. For example, the output of the op-amp 904 drives the gate of an example output transistor 914 (identified as MN_OUT) to cause the voltage at the replica node REP to be equal to the voltage at the node SW1. Thus, the op-amp 904 forces the voltage at the sources of the NMOS transistor 502 and the replica transistor 902 to be equal. Accordingly, the current through the replica transistor 902 and the output transistor 914 is a scaled replica of the current through the NMOS transistor 502. For example, because (1) the same gate-to-source voltage is applied to the NMOS transistor 502 and the replica transistor 902 and (2) the NMOS transistor 502 is N times larger than the replica transistor 902, the current through the replica transistor 902 and the output transistor 914 is

$$\frac{1}{N}$$

times the current through the NMOS transistor 502, which is equal to the current through the inductor 210.

In the illustrated example of FIG. 9, the high-side source mode sensor 806 includes an example sense resistor 916 (identified as R_{SNS}) that converts the replica current into a sensed voltage (identified as VOUT_SNS_SRC). For example, the output transistor 914 applies the replicated current to the sense resistor 916 to convert the replicated current to the sensed voltage. As such, the high-side source mode OI comparator 808 can compare the sensed voltage to the source mode OI reference voltage (identified as VREF_OI_SRC). In some examples, the high-side source mode OI comparator 808 is referred to as an amplifier. As illustrated in FIG. 9, the high-side source mode sensor 806 does not require compensation which allows the high-side source mode sensor 806 to operate over a higher bandwidth and to better track the current through the inductor 210. Additionally, the high-side source mode sensor 806 is active responsive to a finite current through the inductor 210 and when the NMOS transistor 502 is on. Thus, the high-side source mode sensor 806 has low (e.g., minimal) impact on the efficiency of the driver power stage 104.

In the illustrated example of FIG. 9, the replica transistor 902 and the output transistor 914 are N-channel MOSFETs. Alternatively, the replica transistor 902 and the output transistor 914 may be N-channel FETs, N-channel IGBTs, N-channel JFETs, NPN BJTs, or, with slight modifications, P-channel equivalent devices. In the example of FIG. 9, the transistors 906, 908 are P-channel MOSFETs. Alternatively, the transistors 906, 908 may be P-channel FETs, P-channel IGBTs, P-channel JFETs, PNP BJTs, or, with slight modifications, N-channel equivalent devices. The transistors 902, 906, 908, 914 may be depletion mode devices, drain-extended devices, enhancement mode devices, natural transistors, or other type of device structure transistors. Furthermore, the transistors 902, 906, 908, 914 may be implemented in/over a Si substrate, a SiC substrate, a GaN substrate, or a GaAs substrate.

As described above, the high-side source mode OI comparator 808 is calibrated in some examples. For example, the op-amp 904 and the high-side source mode OI comparator 808 introduce errors that can impact when the high-side source mode OI comparator 808 trips with respect to the sensed current and the source mode OI reference voltage (e.g., corresponding to the peak inductor current limit value). In particular, mismatch between the current sources 910, 912 that bias the op-amp 904 can lead to a mismatch or offset between the replicated current and the inductor current. Additionally, an offset between the inputs to the op-amp 904, mismatch between the NMOS transistor 502 and the replica transistor 902, and/or an offset between the inputs to the high-side source mode OI comparator 808 can lead to DC errors in source mode OI event detection. Other sources of DC error include the relative mismatch between the resistance of the sense resistor 916 and the combined resistance of the resistor 1016 and the reference resistor 1022 described below.

In the illustrated example of FIG. 9, the high-side source mode sensor 806 is only active responsive to a finite current through the inductor 210 and when the NMOS transistor 502 is on. Thus, one technique to calibrate the high-side source mode OI comparator 808 for DC errors would be to draw a predefined, precise current through the inductor 210 to ensure that the high-side source mode sensor 806 and the associated feedback loop are operating as expected. For example, once a known reference current is drawn through the inductor 210, the output voltage from the high-side source mode sensor 806 is

$$\frac{IL}{N} * {R}_{SNS} ( e . g . , {VOUT}_{{SNS}_{SRC}} = \frac{IL}{N} * {R}_{SNS} )$$

where N is the ratio of the size of the NMOS transistor 502 to the size of the replica transistor 902.

However, because the high-side source mode sensor 806 operates over a large current range (e.g., from 2 A to 5 A), the current drawn through the inductor 210 would need to be large for calibration to mimic actual operation. Thus, calibration according to this technique would consume significant power and time. Additionally, calibration according to this technique could lead to reliability issues on-chip. For example, for a chip implementing the high-side source mode sensor 806, the maximum rating for DC current that the chip can draw from a supply is about 1.5 A. As such, drawing the currents needed to perform calibration according to this technique may approach or exceed the maximum rating of the chip. Advantageously, in some embodiments, examples described herein do not require a large current to be drawn through the inductor 210 to calibrate the high-side source mode OI comparator 808 for DC errors of the high-side source mode sensor 806 and/or the high-side source mode OI comparator 808.

FIG. 10 is a schematic diagram of an example calibration circuit 1000 for the high-side source mode OI comparator 808 of FIG. 8, according to an embodiment of the present disclosure. In the example of FIG. 10, the calibration circuit 1000 is illustrated relative to the high-side source mode sensor 806 of FIG. 9. To calibrate for the DC errors described above, the mode control state machine 832 controls the driver power stage 104 to couple the nodes SW1 and SW2 to the supply terminal 212. For example, the mode control state machine 832 controls the NMOS transistors 502, 506 to be on and the NMOS transistors 504, 508 to be off. Thus, the voltage across the inductor 210 will be 0V. As such, no current will build up in the inductor 210 during calibration and the current through the inductor 210 in steady state will be 0 A.

In the illustrated example of FIG. 10, after the mode control state machine 832 controls the NMOS transistors 502, 506 to be on and the NMOS transistors 504, 508 to be off, the mode control state machine 832 provides a calibration enable signal (identified as CAL_EN) to a first example calibration switch 1002 to start calibration of the high-side source mode OI comparator 808. Additionally, an inverter (e.g., a NOT gate) provides an inverted calibration enable signal (identified as CAL_ENB) responsive to the calibration enable signal. For example, the inverted calibration enable signal drives a second example calibration switch 1004. Responsive to the calibration enable signal indicating to calibrate the high-side source mode OI comparator 808, the calibration switch 1002 closes and the inverted calibration enable signal drives the calibration switch 1004 to be open. In the example of FIG. 10, the calibration enable signal corresponds to the calibration enable signal identified as CAL_EN1 in FIG. 8.

In the illustrated example of FIG. 10, responsive to the calibration switch 1002 closing and the calibration switch 1004 opening, a first example current source 1006 sets a calibration current (identified as ICAL) through an example current mirror 1008. In the example of FIG. 10, the current mirror 1008 is implemented by example transistors 1010, 1012. As illustrated in FIG. 10, the calibration current is drawn through the transistor 1010 and applied to a first example resistor 1014. For example the resistor 1014 has a resistance of 500R. Responsive to the mirroring action of the current mirror 1008, the calibration current is also drawn through the transistor 1012 and applied to a second example resistor 1016 to generate a reference voltage (identified as V_{REF}) at the inverting input of the high-side source mode OI comparator 808. For example, the resistor 1016 has a resistance of R.

In the illustrated example of FIG. 10, the calibration current drawn through the transistor 1012 is also induced through an example sampling transistor 1018 (identified as MN_SAMP). As such, the sampling transistor 1018 samples the calibration current. As illustrated in FIG. 10, the sampling transistor 1018 is used in parallel with the replica transistor 902. For example, the gates of the replica transistor 902 and the sampling transistor 1018 are coupled together and the controller 802 applies the drive signal for the NMOS transistor 502 to the gates of the replica transistor 902 and the sampling transistor 1018. In the example of FIG. 10, the sampling transistor 1018 is matched to the replica transistor 902. For example, the sampling transistor 1018 is approximately the same size as the replica transistor 902.

In the illustrated example of FIG. 10, the drain of the sampling transistor 1018 is coupled to the node SW1. Because the NMOS transistor 502 is controlled to be on during calibration, the drain of the sampling transistor 1018 is effectively shorted to the supply terminal 212. Thus, responsive to the feedback action of the op-amp 904, the op-amp 904 forces the voltage at the replica node (identified as REP) to be equal to or within an acceptable range of the voltage at the supply terminal 212. As such, the op-amp 904 forces the voltage at the sources of the sampling transistor 1018 and the replica transistor 902 to be equal. Accordingly, the replica transistor 902 replicates the current through the sampling transistor 1018. For example, because (1) the same gate-to-source voltage is applied to the sampling transistor 1018 and the replica transistor 902 and (2) the sampling transistor 1018 is the same size as the replica transistor 902, the current through the replica transistor 902 and the output transistor 914 is approximately equal to the current through the sampling transistor 1018, which is equal to the calibration current.

In the illustrated example of FIG. 10, the output transistor 914 applies the calibration current to the sense resistor 916 to generate the sensed voltage (identified as VOUT_SNS_SRC) at the non-inverting input of the high-side source mode OI comparator 808. In the example of FIG. 10, the resistance of the sense resistor 916 is matched to the resistance of the resistor 1016. For example, the sense resistor 916 and the resistor 1016 have the same resistance. In some examples, the resistance of the sense resistor 916 is scaled with respect to the resistance of the resistor 1016. As such, the high-side source mode OI comparator 808 can compare the sensed voltage to the reference voltage, both of which are based on the calibration current.

In the illustrated example of FIG. 10, after the calibration switch 1002 has been closed and the calibration switch 1004 has been opened, the mode control state machine 832 provides a trim signal (identified as TRIM1) to set a trim code for the high-side source mode OI comparator 808. For example, the high-side source mode OI comparator 808 has a programmable offset between the inverting and non-inverting inputs of the high-side source mode OI comparator 808. Additionally, the dynamic range of the programmable offset is designed to cover DC error sources described herein. As such, the mode control state machine 832 sweeps through (e.g., applies one or more) trim codes of the high-side source mode OI comparator 808 until the high-side source mode OI comparator 808 trips (e.g., indicates that a source mode OI event was detected). For example, the mode control state machine 832 sets the trim code for the high-side source mode OI comparator 808 to be the trim code at which the high-side source mode OI comparator 808 tripped. In the example of FIG. 10, the trim signal corresponds to the trim signal identified as TRIM1 in FIG. 8.

In the illustrated example of FIG. 10, after setting the trim code for the high-side source mode OI comparator 808, the mode control state machine 832 adjusts the driver power stage 104 and the calibration circuit 1000 for normal operation (e.g., non-calibration operation). For example, the mode control state machine 832 provides the calibration enable signal (identified as CAL_EN) to indicate that calibration has concluded. Additionally, the mode control state machine 832 controls the NMOS transistors 502-508 to be in an idle state. Thus, the mode control state machine 832 can control the NMOS transistors 502-508 responsive to the PWM signal as described above. In the example of FIG. 10, responsive to the calibration signal indicating calibration has concluded, the calibration switch 1002 opens and the inverted calibration enable signal (identified as CAL_ENB) drives the calibration switch 1004 to be closed.

In the illustrated example of FIG. 10, responsive to the calibration switch 1002 opening and the calibration switch 1004 closing, a second example current source 1020 sets a reference current through an example reference resistor 1022 (identified as R_{REF}) and the resistor 1016. For example, the reference current is six microamps (μA) (e.g., I_{REF}=6 μA). During normal operation, the source mode OI reference voltage (identified as VREF_OI_SRC) is equal to the voltage across the reference resistor 1022 and the resistor 1016. As such, a user of the system 800 can tune the resistance of the reference resistor 1022 (e.g., a variable resistor) to adjust the source mode OI reference voltage and therefore adjust the source mode OI limit for the driver power stage 104.

In the illustrated example of FIG. 10, by utilizing the high-side source mode OI comparator 808 during calibration, the calibration circuit 1000 ensures that DC errors arising from the high-side source mode OI comparator 808 are compensated for in addition to those arising from the high-side source mode sensor 806. Additionally, the mode control state machine 832 does not need to monitor the calibration current set by the current source 1006 because the same current is replicated between the inverting and the non-inverting inputs of the high-side source mode OI comparator 808. As such, calibration of the high-side source mode OI comparator 808 is simplified.

Furthermore, the calibration current utilized by the calibration circuit 1000 is relatively small compared to other techniques. For example, the calibration current is between 1 mA and 3 mA (e.g., 3 mA≥ICAL≥1 mA). Additionally, the calibration circuit 1000 does not draw current through the inductor 210 during calibration and the calibration current utilized by the calibration circuit 1000 is independent of the set OI limit. As such, calibration of the high-side source mode OI comparator 808 consumes less power than other approaches and occurs over a shorter period of time than other approaches.

Additionally, described calibration improves the accuracy of OI event detection and therefore enables the driver power stage 104 to operate relatively closer to the OI limit (and corresponding saturation current level) for the inductor 210 during normal operation. For example, when utilizing example calibration described herein, DC accuracy for sensing an OI event during normal operation is ±25 mA. By increasing the peak inductor current capability, example calibration described herein increases (e.g., maximizes) output power from the driver power stage 104. Additionally, example calibration described herein reduces offset requirements for the high-side source mode sensor 806 and for the high-side source mode OI comparator 808 which allows for a more compact design. Also, example calibration described herein does not present reliability concerns that are present in other calibration approaches.

In the illustrated example of FIG. 10, the transistors 1010, 1012, 1018 are N-channel MOSFETs. Alternatively, the transistors 1010, 1012, 1018 may be N-channel FETs, N-channel IGBTs, N-channel JFETs, NPN BJTs, or, with slight modifications, P-channel equivalent devices. The transistors 1010, 1012, 1018 may be depletion mode devices, drain-extended devices, enhancement mode devices, natural transistors, or other type of device structure transistors. Furthermore, the transistors 1010, 1012, 1018 may be implemented in/over a Si substrate, a SiC substrate, a GaN substrate, or a GaAs substrate.

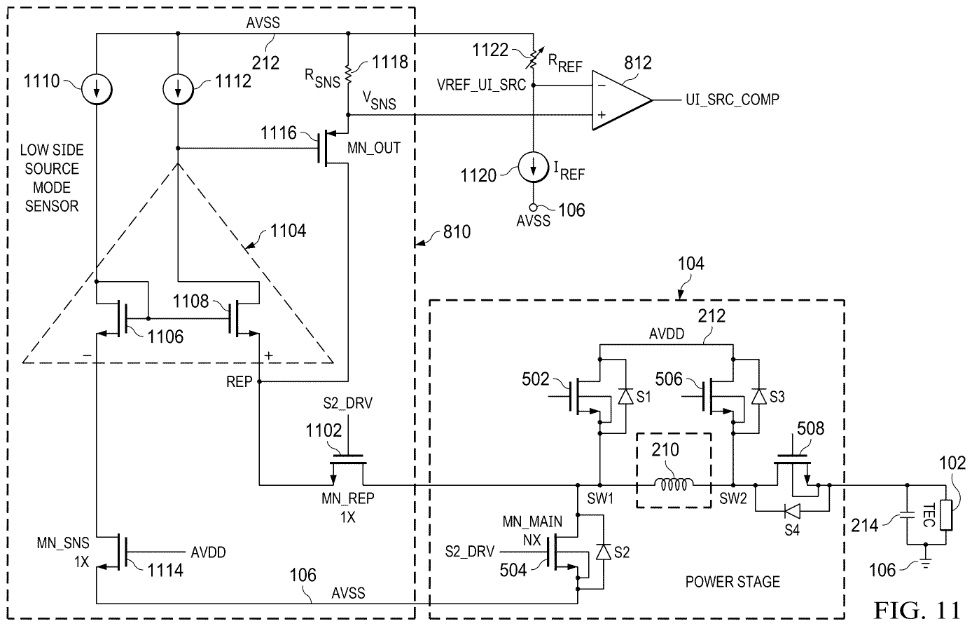

FIG. 11 is a schematic diagram of the low-side source mode sensor 810 of FIG. 8, according to an embodiment of the present disclosure. As described above, current through the inductor 210 flows from the node SW1 to the node SW2 in source mode and the low-side source mode sensor 810 senses the current through the switch 204 to monitor for a source mode UI event. In the example of FIG. 11, the low-side source mode sensor 810 is illustrated relative to the driver power stage 104 of FIG. 5. For example, the low-side source mode sensor 810 includes an example replica transistor 1102 (identified as MN_REP) that is used in parallel with the NMOS transistor 504 to monitor the current through the NMOS transistor 504. For example, the controller 802 applies the drive signal for the NMOS transistor 504 to the gates of the NMOS transistor 504 and the replica transistor 1102. In the example of FIG. 11, the replica transistor 1102 is

$$\frac{1}{N}$$

times the size of the NMOS transistor 504.

In the illustrated example of FIG. 11, the low-side source mode sensor 810 also includes an example op-amp 1104 that is implemented in the current domain to achieve a quicker response time for sensing (e.g., determining) the current through the NMOS transistor 504. In the example of FIG. 11, the op-amp 1104 is implemented by a current input amplifier including an NMOS input pair of example transistors 1106, 1108. For example, the source of the transistor 1106 corresponds to the inverting input of the op-amp 1104 and the source of the transistor 1108 corresponds to the non-inverting input of the op-amp 1104. Additionally, the drain of the transistor 1108 corresponds to the output of the op-amp 1104. In the example of FIG. 11, the transistor 1106 is biased by a first example current source 1110 and the transistor 1108 is biased by a second example current source 1112.

In the illustrated example of FIG. 11, the inverting input of the op-amp 1104 is coupled to the common terminal 106 through an example sense transistor 1114 (identified as MN_SNS) and the non-inverting input of the op-amp 1104 is coupled to the replica transistor 1102. In the example of FIG. 11, the sense transistor 1114 is

$$\frac{1}{N}$$

times the size of the NMOS transistor 504. As illustrated in FIG. 11, the gate of the sense transistor 1114 is driven by the supply terminal 212. Thus, when the replica transistor 1102 is on, the sense transistor 1114 pulls the inverting input of the op-amp 1104 to the voltage at the common terminal 106. Responsive to the feedback action of the op-amp 1104, the op-amp 1104 forces the voltage at the replica node (identified as REP) to be equal to or within an acceptable range of the voltage at the common terminal 106.

For example, the output of the op-amp 1104 drives the gate of output transistor 1116 (identified as MN_OUT) to cause the voltage at the inverting and non-inverting inputs of the op-amp 1104 to be equal. In the example of FIG. 11, the voltage at the inverting input of the op-amp 1104 is close to the voltage at the common terminal 106. As such, the op-amp 1104 causes the voltage at the non-inverting input of the op-amp 1104 (e.g., the replica node REP) to be equal to the voltage at the common terminal 106. Thus, the op-amp 1104 forces the voltage at the source of the replica transistor 1102 to be equal the voltage at the common terminal 106, which is also the voltage at the source of the NMOS transistor 504. Accordingly, the current through the replica transistor 1102 and the output transistor 1116 is a scaled replica of the current through the NMOS transistor 504. For example, because (1) the same gate-to-source voltage is applied to the NMOS transistor 504 and the replica transistor 1102 and (2) the NMOS transistor 504 is N times larger than the replica transistor 1102, the current through the replica transistor 1102 and the output transistor 1116 is

$$\frac{1}{N}$$

times the current through the NMOS transistor 502, which is equal to the current through the inductor 210.

In the illustrated example of FIG. 11, the low-side source mode sensor 810 includes an example sense resistor 1118 (identified as R_{SNS}) that converts the replica current into a sensed voltage (identified as V_{SNS}). For example, the output transistor 1116 pulls the replicated current through the sense resistor 1118 to convert the replicated current to the sensed voltage. In the example of FIG. 11, the sensed voltage is equal to the difference between the voltage at the supply terminal 212 and the product of the resistance of the sense resistor 1118 and the replica current

$$( e . g . , {V}_{SNS} = AVDD - \frac{IL}{N} * {R}_{SNS} ) .$$

As such, the low-side source mode UI comparator 812 can compare the sensed voltage to the source mode UI reference voltage (identified as VREF_UI_SRC) which, in the example of FIG. 11, is generated by a third example current source 1120 pulling a reference current (identified as I_{REF}) through an example reference resistor 1122 (identified as R_{REF}). In some examples, the low-side source mode UI comparator 812 is referred to as an amplifier.

In the illustrated example of FIG. 11, the low-side source mode sensor 810 achieves similar benefits to the high-side source mode sensor 806 of FIG. 9. Additionally, the low-side source mode sensor 810 is not calibrated as the source mode UI reference voltage (e.g., corresponding to the source mode UI threshold) can be intentionally skewed to cover for DC errors without impacting the peak inductor current limit. For example, a user of the system 800 can tune the resistance of the reference resistor 1122 (e.g., a variable resistor) to adjust the source mode UI reference voltage to cover for DC errors introduced by the low-side source mode sensor 810 and the low-side source mode UI comparator 812. By skewing the source mode UI reference voltage, DC accuracy for sensing a UI event during normal operation is ±200 mA.

In the illustrated example of FIG. 11, the transistors 1102, 1106, 1108, 1114 are N-channel MOSFETs. Alternatively, the transistors 1102, 1106, 1108, 1114 may be N-channel FETs, N-channel IGBTs, N-channel JFETs, NPN BJTs, or, with slight modifications, P-channel equivalent devices. In the example of FIG. 11, the transistor 1116 is a P-channel MOSFET. Alternatively, the transistor 1116 may be a P-channel FET, a P-channel IGBT, a P-channel JFET, a PNP BJT, or, with slight modifications, an N-channel equivalent device. The transistors 1102, 1106, 1108, 1114, 1116 may be depletion mode devices, drain-extended devices, enhancement mode devices, natural transistors, or other type of device structure transistors. Furthermore, the transistors 1102, 1106, 1108, 1114, 1116 may be implemented in/over a Si substrate, a SiC substrate, a GaN substrate, or a GaAs substrate.

FIG. 12 is a schematic diagram of the low-side sink mode sensor 814 of FIG. 8 and calibration circuit 1200 for the low-side sink mode OI comparator 816 of FIG. 8, according to an embodiment of the present disclosure. As described above, current through the inductor 210 flows from the node SW2 to the node SW1 in sink mode and the low-side sink mode sensor 814 senses the current through the switch 204 to monitor for a sink mode OI event. In the example of FIG. 12, the low-side sink mode sensor 814 and the calibration circuit 1200 are illustrated relative to the driver power stage 104 of FIG. 5. For example, the low-side sink mode sensor 814 includes replica transistor 1202 (identified as MN_REP) that is used in parallel with the NMOS transistor 504 to monitor the current through the NMOS transistor 504. For example, the controller 802 applies the drive signal for the NMOS transistor 504 to the gates of the NMOS transistor 504 and the replica transistor 1202. In the example of FIG. 12, the replica transistor 1202 is

$$\frac{1}{N}$$

times the size or the NMOS transistor 504.

In the illustrated example of FIG. 12, the low-side sink mode sensor 814 also includes an example op-amp 1204 that is implemented in the current domain to achieve a quicker response time for sensing the current through the NMOS transistor 504. In the example of FIG. 12, the op-amp 1204 is implemented by a current input amplifier including an NMOS input pair of example transistors 1206, 1208. For example, the source of the transistor 1206 corresponds to the inverting input of the op-amp 1204 and the source of the transistor 1208 corresponds to the non-inverting input of the op-amp 1204. Additionally, the drain of the transistor 1208 corresponds to the output of the op-amp 1204. In the example of FIG. 12, the transistor 1206 is biased by a first example current source 1210 and the transistor 1208 is biased by a second example current source 1212.

In the illustrated example of FIG. 12, the inverting input of the op-amp 1204 is coupled to an example sampling transistor 1214 (identified as MN_SAMP) and the non-inverting input of the op-amp 1204 is coupled to the common terminal 106 through the replica transistor 1202. In the example of FIG. 12, the sampling transistor 1214 is

$$\frac{1}{N}$$

times the size of the NMOS transistor 504. As illustrated in FIG. 12, the gate of the sampling transistor 1214 is driven by the supply terminal 212. Thus, the inverting input of the op-amp 1204 is set to the voltage at the node SW1. Accordingly, when the replica transistor 1202 is on, the feedback action of the op-amp 1204 forces the voltage at the replica node (identified as REP) to be equal to or within an acceptable range of the voltage at the node SW1.

For example, the output of the op-amp 1204 drives the gate of an example output transistor 1216 (identified as MN_OUT) to cause the voltage at the replica node REP to be equal to the voltage at the node SW1. As the voltages at gate, drain, and source of the replica transistor 1202 and the NMOS transistor 504 are equal, the current through the replica transistor 1202 and the output transistor 1216 is a scaled replica of the current through the NMOS transistor 504. For example, because (1) the same gate-to-source voltage is applied to the NMOS transistor 504 and the replica transistor 1202 and (2) the NMOS transistor 504 is N times larger than the replica transistor 1202, the current through the replica transistor 1202 and the output transistor 1216 is

$$\frac{1}{N}$$

times the current through the NMOS transistor 502, which is equal to the current through the inductor 210.

In the illustrated example of FIG. 12, the low-side sink mode sensor 814 includes an example sense resistor 1218 (identified as R_{SNS}) that converts the replica current into a sensed voltage (identified as V_{SNS}). For example, the output transistor 1216 pulls the replicated current through the sense resistor 1218 to convert the replicated current to the sensed voltage. In the example of FIG. 12, the sensed voltage is equal to the difference between the voltage at the supply terminal 212 and the product of the resistance of the sense resistor 1218 and the replica current

$$( e . g . , {V}_{SNS} = AVDD - \frac{IL}{N} * {R}_{SNS} ) .$$

As such, the low-side sink mode OI comparator 816 can compare the sensed voltage to the sink mode OI reference voltage (identified as VREF_OI_SNK). Additionally, the low-side sink mode UI comparator 818 can compare the sensed voltage to the low-side sink mode UI reference voltage (identified as VREF_UI_SNK). In some examples, the low-side sink mode OI comparator 816 and the low-side sink mode UI comparator 818 are referred to as amplifiers. In the example of FIG. 12, the low-side sink mode sensor 814 achieves similar benefits to the high-side source mode sensor 806 of FIG. 9 and the low-side source mode sensor 810 of FIG. 11.

As described above, the low-side sink mode OI comparator 816 is calibrated in some examples. For example, the op-amp 1204 and the low-side sink mode OI comparator 816 introduce errors that can impact when the low-side sink mode OI comparator 816 trips with respect to the sensed current and the sink mode OI reference voltage (e.g., corresponding to the peak inductor current limit value). In particular, mismatch between the current sources 1210, 1212 that bias the op-amp 1204 can lead to a mismatch or offset between the replicated current and the inductor current. Additionally, an offset between the inputs to the op-amp 1204, mismatch between the NMOS transistor 504 and the replica transistor 1202, and/or an offset between the inputs to the low-side sink mode OI comparator 816 can lead to DC errors in sink mode OI event detection. Other sources of DC error include the relative mismatch between the resistance of the sense resistor 1218 and the combined resistance of the resistor 1234 and the reference resistor 1238 described below.

As described above, example calibration described herein, advantageously does not require a large current to be drawn through the inductor 210 to calibrate the low-side sink mode OI comparator 816 for DC errors of the low-side sink mode sensor 814 and/or the low-side sink mode OI comparator 816, in some embodiments. To calibrate for the DC errors described above, the mode control state machine 832 controls the driver power stage 104 to couple the node SW1 to the common terminal 106 and to couple the node SW2 to the output terminal of the driver power stage 104. For example, the mode control state machine 832 controls the NMOS transistors 502, 506 to be off and the NMOS transistors 504, 508 to be on. Thus, the output voltage from the driver power stage 104 is discharged to 0V. As such, no current will build up in the inductor 210 during calibration and the current through the inductor 210 in steady state will be 0 A.

In the illustrated example of FIG. 12, after the mode control state machine 832 controls the NMOS transistors 502, 506 to be off and the NMOS transistors 504, 508 to be on, the mode control state machine 832 provides a calibration enable signal (identified as CAL_EN) to a first example calibration switch 1220 to start calibration of the low-side sink mode OI comparator 816. Additionally, an inverter (e.g., a NOT gate) provides an inverted calibration enable signal (identified as CAL_ENB) responsive to the calibration enable signal. For example, the inverted calibration enable signal drives a second example calibration switch 1222. Responsive to the calibration enable signal indicating to calibrate the low-side sink mode OI comparator 816, the calibration switch 1220 closes and the inverted calibration enable signal drives the calibration switch 1222 to be open. In the example of FIG. 12, the calibration enable signal corresponds to the calibration enable signal identified as CAL_EN2 in FIG. 8.

In the illustrated example of FIG. 12, responsive to the calibration switch 1220 closing and the calibration switch 1222 opening, a third example current source 1224 sets a calibration current (identified as ICAL) through an example current mirror 1226. In the example of FIG. 12, the current mirror 1226 is implemented by example transistor 1228, 1230. As illustrated in FIG. 12, the calibration current is drawn through the transistor 1228 and applied to a first example resistor 1232. For example the resistor 1232 has a resistance of 500R. Responsive to the mirroring action of the current mirror 1226, the calibration current is also drawn through the transistor 1230 and applied to a second example resistor 1234 to generate a reference voltage (identified as V_{REF}) at the inverting input of the low-side sink mode OI comparator 816. For example, the resistor 1234 has a resistance of R.

In the illustrated example of FIG. 12, the calibration current drawn through the transistor 1230 is also induced through the sampling transistor 1214. As such, the sampling transistor 1214 samples the calibration current. As described above, the sampling transistor 1214 is used in parallel with the replica transistor 1202 and the controller 802 applies the drive signal for the NMOS transistor 504 to the gates of the replica transistor 1202 and the sampling transistor 1214. Also, as described above, the sampling transistor 1214 is matched to the replica transistor 1202. For example, the sampling transistor 1214 is approximately the same size as the replica transistor 1202.

In the illustrated example of FIG. 12, the drain of the sampling transistor 1214 is coupled to the node SW1. Because the NMOS transistor 504 is controlled to be on during calibration, the drain of the sampling transistor 1214 is effectively shorted to the common terminal 106. Thus, responsive to the feedback action of the op-amp 1204, the op-amp 1204 forces the voltage at the replica node (identified as REP) to be equal to or within an acceptable range of the voltage at the common terminal 106. As such, the op-amp 1204 forces the voltage at the source of the sampling transistor 1214 and at the drain of the replica transistor 1202 to be equal. Accordingly, the replica transistor 1202 replicates the current through the sampling transistor 1214. For example, because (1) the sampling transistor 1214 and the replica transistor 1202 are both on and (2) the sampling transistor 1214 is the same size as the replica transistor 1202, the current through the replica transistor 1202 and the output transistor 1216 is approximately equal to the current through the sampling transistor 1214, which is equal to the calibration current.

In the illustrated example of FIG. 12, the output transistor 1216 applies the calibration current to the sense resistor 1218 to generate the sensed voltage (identified as V_{SNS}) at the non-inverting input of the low-side sink mode OI comparator 816. In the example of FIG. 12, the resistance of the sense resistor 1218 is matched to the resistance of the resistor 1234. For example, the sense resistor 1218 and the resistor 1234 have the same resistance. In some examples, the resistance of the sense resistor 1218 is scaled with respect to the resistance of the resistor 1234. As such, the low-side sink mode OI comparator 816 can compare the sensed voltage to the reference voltage, both of which are based on the calibration current.

In the illustrated example of FIG. 12, after the calibration switch 1220 has been closed and the calibration switch 1222 has been opened, the mode control state machine 832 provides a trim signal (identified as TRIM2) to set a trim code for the low-side sink mode OI comparator 816. For example, the low-side sink mode OI comparator 816 has a programmable offset between the inverting and non-inverting inputs of the low-side sink mode OI comparator 816. Additionally, the dynamic range of the programmable offset is designed to cover DC error sources described herein. As such, the mode control state machine 832 sweeps through (e.g., applies one or more) trim codes of the low-side sink mode OI comparator 816 until the low-side sink mode OI comparator 816 trips (e.g., indicates that a sink mode OI event was detected). For example, the mode control state machine 832 sets the trim code for the low-side sink mode OI comparator 816 to be the trim code at which the low-side sink mode OI comparator 816 tripped. In the example of FIG. 12, the trim signal corresponds to the trim signal identified as TRIM2 in FIG. 8.

In the illustrated example of FIG. 12, after setting the trim code for the low-side sink mode OI comparator 816, the mode control state machine 832 adjusts the driver power stage 104 and the calibration circuit 1200 for normal operation (e.g., non-calibration operation). For example, the mode control state machine 832 provides the calibration enable signal (identified as CAL_EN) to indicate that calibration has concluded. Additionally, the mode control state machine 832 controls the NMOS transistors 502-508 to be in an idle state. Thus, the mode control state machine 832 can control the NMOS transistors 502-508 responsive to the PWM signal as described above. In the example of FIG. 12, responsive to the calibration signal indicating calibration has concluded, the calibration switch 1220 opens and the inverted calibration enable signal (identified as CAL_ENB) drives the calibration switch 1222 to be closed.

In the illustrated example of FIG. 12, responsive to the calibration switch 1220 opening and the calibration switch 1222 closing, a fourth example current source 1236 sets a reference current (identified as I_{REF}) through an example reference resistor 1238 (identified as R_{REF}) and the resistor 1234. During normal operation, the sink mode OI reference voltage (identified as VREF_OI_SNK) is equal to the voltage across the reference resistor 1238 and the resistor 1234. As such, a user of the system 800 can tune the resistance of the reference resistor 1238 (e.g., a variable resistor) to adjust the sink mode OI reference voltage and therefore adjust the sink mode OI limit for the driver power stage 104.

In the illustrated example of FIG. 12, by utilizing the low-side sink mode OI comparator 816 during calibration, the calibration circuit 1200 ensures that DC errors arising from the low-side sink mode OI comparator 816 are compensated for in addition to those arising from the low-side sink mode sensor 814. Additionally, the mode control state machine 832 does not need to monitor the calibration current set by the current source 1224 because the same current is replicated between the inverting and the non-inverting inputs of the low-side sink mode OI comparator 816. As such, calibration of the low-side sink mode OI comparator 816 is simplified.

Furthermore, the calibration current utilized by the calibration circuit 1200 is relatively small compared to other techniques. For example, the calibration current is between 1 mA and 3 mA (e.g., 3 mA≥ICAL≥1 mA). Additionally, the calibration circuit 1200 does not draw current through the inductor 210 during calibration and the calibration current utilized by the calibration circuit 1200 is independent of the set OI limit. As such, calibration of the low-side sink mode OI comparator 816 consumes less power than other approaches and occurs over a shorter period of time than other approaches.

Additionally, described calibration improves the accuracy of OI event detection and therefore enables the driver power stage 104 to operate relatively closer to the OI limit (and corresponding saturation current level) for the inductor 210 during normal operation. For example, when utilizing example calibration described herein, DC accuracy for sensing an OI event during normal operation is ±25 mA. By increasing the peak inductor current capability, example calibration described herein increases (e.g., maximizes) output power from the driver power stage 104. Additionally, example calibration described herein reduces offset requirements for the low-side sink mode sensor 814 and for the low-side sink mode OI comparator 816 which allows for a more compact design. Also, example calibration described herein does not present reliability concerns that are present in other calibration approaches.

In the illustrated example of FIG. 12, the low-side sink mode UI comparator 818 is not calibrated as the low-side sink mode UI reference voltage (e.g., corresponding to the low-side sink mode UI threshold) can be intentionally skewed to cover for DC errors without impacting the peak inductor current limit. For example, a user of the system 800 can tune the resistance of the reference resistor 1238 to adjust the low-side sink mode UI reference voltage to cover for DC errors introduced by the low-side sink mode sensor 814 and the low-side sink mode UI comparator 818. By skewing the low-side sink mode UI reference voltage, DC accuracy for sensing a UI event during normal operation is ±200 mA.

In the illustrated example of FIG. 12, the transistors 1202, 1206, 1208, 1214 are N-channel MOSFETs. Alternatively, the transistors 1202, 1206, 1208, 1214 may be N-channel FETs, N-channel IGBTs, N-channel JFETs, NPN BJTs, or, with slight modifications, P-channel equivalent devices. In the example of FIG. 12, the transistors 1216, 1228, 1230 are P-channel MOSFETs. Alternatively, the transistors 1216, 1228, 1230 may be P-channel FETs, P-channel IGBTs, P-channel JFETs, PNP BJTs, or, with slight modifications, N-channel equivalent devices. The transistors 1202, 1206, 1208, 1214, 1216, 1228, 1230 may be depletion mode devices, drain-extended devices, enhancement mode devices, natural transistors, or other type of device structure transistors. Furthermore, the transistors 1202, 1206, 1208, 1214, 1216, 1228, 1230 may be implemented in/over a Si substrate, a SiC substrate, a GaN substrate, or a GaAs substrate.

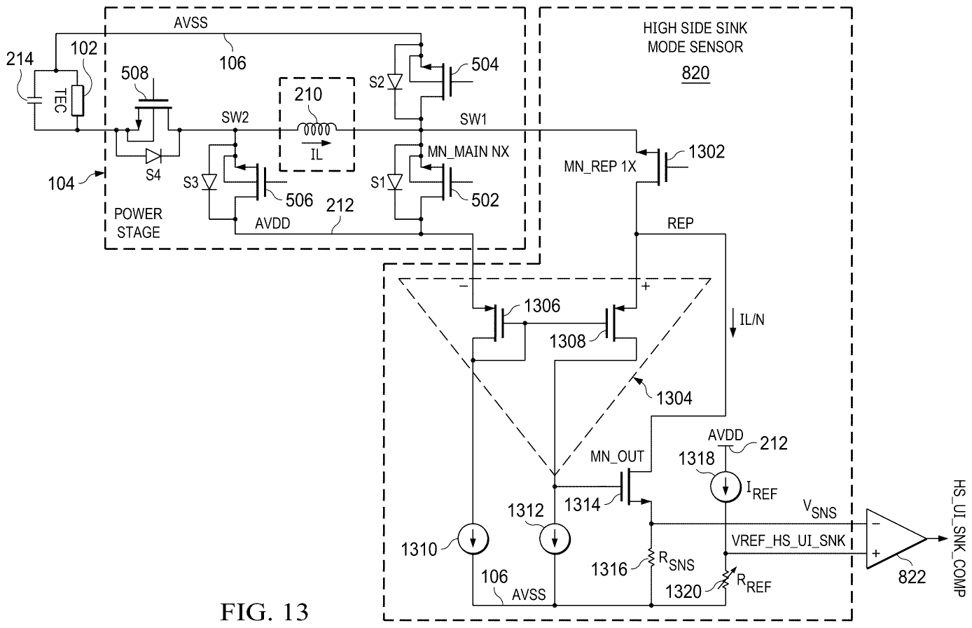

FIG. 13 is a schematic diagram of the high-side sink mode sensor 820 of FIG. 8, according to an embodiment of the present disclosure. As described above, current through the inductor 210 flows from the node SW2 to the node SW1 in sink mode and the high-side sink mode sensor 820 senses the current through the switch 202 to monitor for a high-side sink mode UI event. In the example of FIG. 13, the high-side sink mode sensor 820 is illustrated relative to the driver power stage 104 of FIG. 5. For example, the high-side sink mode sensor 820 includes an example replica transistor 1302 (identified as MN_REP) that is used in parallel with the NMOS transistor 502 to monitor the current through the NMOS transistor 502. For example, the controller 802 applies the drive signal for the NMOS transistor 502 to the gates of the NMOS transistor 502 and the replica transistor 1302. In the example of FIG. 13, the replica transistor 1302 is

$$\frac{1}{N}$$

times the size of the NMOS transistor 502.

In the illustrated example of FIG. 13, the high-side sink mode sensor 820 also includes an example operational amplifier (op-amp) 1304 that is implemented in the current domain to achieve a quicker response time for sensing the current through the NMOS transistor 502. In the example of FIG. 13, the op-amp 1304 is implemented by a current input amplifier including a PMOS input pair of example transistors 1306, 1308. For example, the source of the transistor 1306 corresponds to the inverting input of the op-amp 1304 and the source of the transistor 1308 corresponds to the non-inverting input of the op-amp 1304. Additionally, the drain of the transistor 1308 corresponds to the output of the op-amp 1304. In the example of FIG. 13, the transistor 1306 is biased by a first example current source 1310 and the transistor 1308 is biased by a second example current source 1312.

In the illustrated example of FIG. 13, responsive to the feedback action of the op-amp 1304, the op-amp 1304 forces the voltage at the replica node (identified as REP) to be equal to or within an acceptable range of the voltage at the supply terminal 212. For example, the output of the op-amp 1304 drives the gate of an example output transistor 1314 (identified as MN_OUT) to cause the voltage at the replica node REP to be equal to the voltage at the supply terminal 212. Thus, the op-amp 1304 forces the voltage at the drains of the NMOS transistor 502 and the replica transistor 1302 to be equal. Because (1) the same gate-to-source voltage is applied to the NMOS transistor 502 and the replica transistor 1302 and (2) the NMOS transistor 502 is N times larger than the replica transistor 1302, the current through the replica transistor 1302 and the output transistor 1314 is

$$\frac{1}{N}$$

times the current through the NMOS transistor 502, which is equal to the current through the inductor 210. In this manner, the current through the replica transistor 1302 and the output transistor 1314 is a scaled replica of the current through the NMOS transistor 502.

In the illustrated example of FIG. 13, the high-side sink mode sensor 820 includes an example sense resistor 1316 (identified as R_{SNS}) that converts the replica current into a sensed voltage (identified as V_{SNS}). For example, the output transistor 1314 applies the replicated current to the sense resistor 1316 to convert the replicated current to the sensed voltage. As such, the high-side sink mode UI comparator 822 can compare the sensed voltage to the high-side sink mode UI reference voltage (identified as VREF_HS_UI_SNK) which, in the example of FIG. 13, is generated by a third example current source 1318 pulling a reference current (identified as I_{REF}) through an example reference resistor 1320 (identified as R_{REF}). In some examples, the high-side sink mode UI comparator 822 is referred to as an amplifier.

In the illustrated example of FIG. 13, the high-side sink mode sensor 820 achieves similar benefits to the high-side source mode sensor 806 of FIG. 9, the low-side source mode sensor 810 of FIG. 11, and the low-side sink mode sensor 814 of FIG. 12. Additionally, the high-side sink mode sensor 820 is not calibrated as the high-side sink mode UI reference voltage (e.g., corresponding to the high-side sink mode UI threshold) can be intentionally skewed to cover for DC errors without impacting the peak inductor current limit. For example, a user of the system 800 can tune the resistance of the reference resistor 1320 (e.g., a variable resistor) to adjust the high-side sink mode UI reference voltage to cover for DC errors introduced by the high-side sink mode sensor 820 and the high-side sink mode UI comparator 822. By skewing the high-side sink mode UI reference voltage, DC accuracy for sensing a UI event during normal operation is ±200 mA.

In the illustrated example of FIG. 13, the transistors 1302, 1314 are N-channel MOSFETs. Alternatively, the transistors 1302, 1314 may be N-channel FETs, N-channel IGBTs, N-channel JFETs, NPN BJTs, or, with slight modifications, P-channel equivalent devices. In the example of FIG. 13, the transistors 1306, 1308 are P-channel MOSFETs. Alternatively, the transistors 1306, 1308 may be P-channel FETs, P-channel IGBTs, P-channel JFETs, PNP BJTs, or, with slight modifications, N-channel equivalent devices. The transistors 1302, 1314, 1306, 1308 may be depletion mode devices, drain-extended devices, enhancement mode devices, natural transistors, or other type of device structure transistors. Furthermore, the transistors 1302, 1314, 1306, 1308 may be implemented in/over a Si substrate, a SiC substrate, a GaN substrate, or a GaAs substrate.

As described above, e.g., in FIGS. 8-13, examples described herein include an array of high bandwidth inherently stable current input amplifiers to sense one of the switching nodes (e.g., the node SW1) of the driver power stage 104. Each amplifier generates an amplified version of the voltage across a monitored switch. For example, two current input amplifiers monitor the current through the high-side switch (e.g., the switch 202) for overcurrent protection, one each in source mode (e.g., for positive inductor currents) and sink mode (e.g., for negative inductor currents). Additionally, two current input amplifiers monitor the current through the low-side switch (e.g., the switch 204) for overcurrent protection, one each in source mode (e.g., for positive inductor currents) and sink mode (e.g., for negative inductor currents). Thus, the array of amplifiers supports current sensing in both positive and negative directions.

As described above, e.g., in FIGS. 8-13, the sensed voltages of the four sensors are compared against respective programmable DC references using an array of comparators. For example, the amplified value provided by each sensor is compared against a reference using a DC comparator to generate overcurrent decisions in both positive and negative directions. As described above, a calibration circuit is added to two of the sensors to pull a predefined current from one of the nodes of the sensors to set up a feedback loop and reduce (e.g., eliminate) DC errors. In examples described herein, a preliminary digital state machine (e.g., the OI/UI state machine 824) samples, deglitches, and generates two overcurrent detections signals and passes the two overcurrent detection signals to a subsequent digital state machine (e.g., the mode control state machine 832).

As such, some embodiments facilitate the use of a single power inductor to manage the current and voltage supplied by a single ended driver power stage. By limiting the peak instantaneous current through the power inductor on a cycle-by-cycle basis for both positive and negative current, some embodiments avoid degraded performance. For example, the peak instantaneous current through the power inductor is limited to a value that is less than the saturation current limit for the power inductor. Thus, examples described herein avoid degraded performance that would otherwise occur if the power inductor were to saturate.

Additionally, some embodiments reduce DC error in overcurrent detection to less than 25 mA (e.g., DC error <±25 mA) while supporting inductors with a wide range of saturation current (e.g., from 2 A to 5 A). Some embodiments also support overcurrent limiting in the three operations modes described herein (e.g., buck mode, inverting buck-boost mode, and intermediate mode) for both positive and negative currents. Thus, by providing accurate overcurrent monitoring across all modes of operation, some embodiments permit the current limit for the power inductor to be set very close to the saturation current limit. Furthermore, in some embodiments, the overcurrent monitoring has minimal impact on the efficiency of the driver power stage and is area efficient.

FIG. 14 is a schematic diagram of the source mode state machine 828 of FIG. 8, according to an embodiment of the present disclosure. In the example of FIG. 14, the source mode state machine 828 includes level shifters 1402, 1404 to level shift down the drive signals for the switches 202, 204, respectively. Additionally, the source mode state machine 828 includes example programmable delay deglitching circuits 1406, 1408 to deglitch the level shifted drive signals, respectively. In the example of FIG. 14, the source mode state machine 828 includes example delay circuits 1410, 1412 that introduce a delay to the level shifted, deglitched drive signals, respectively.

In the illustrated example of FIG. 14, the source mode state machine 828 includes a first AND gate 1414 to perform a logic AND operation on the level shifted, deglitched, delayed drive signal for the switch 202 and the OI source mode signal (identified as OI_SRC_COMP). In the example of FIG. 14, the output of the AND gate 1414 drives the clock input of a first flip-flop 1416 having a data input coupled to the supply terminal 212 and a clear input coupled to the output of the programmable delay deglitching circuit 1406. The output of the flip-flop 1416 drives the set input of a set, reset (SR) latch 1418.

In the illustrated example of FIG. 14, the source mode state machine 828 also includes a second AND gate 1420 to perform a logic AND operation on the level shifted, deglitched, delayed drive signal for the switch 204 and the UI source mode signal (identified as UI_SRC_COMP). In the example of FIG. 14, the output of the AND gate 1420 drives the clock input of a second flip-flop 1422 having a data input coupled to the supply terminal 212 and a clear input coupled to the output of the programmable delay deglitching circuit 1408. The output of the flip-flop 1422 drives the reset input of the SR latch 1418. In the example of FIG. 14, the output of the SR latch 1418 provides the source mode OI detection signal (identified as OI_SRC_VD).

In the illustrated example of FIG. 14, responsive to the OI source mode signal indicating that a source mode OI event was detected and a close value on the drive signal for the switch 202 (e.g., indicating the switch 202 is to be closed), the source mode state machine 828 sets the source mode OI detection signal to indicate that a source mode OI event was detected. Responsive to the UI source mode signal indicating that a source mode UI event was detected and a close value on the drive signal for the switch 204 (e.g., indicating the switch 204 is to be closed), the source mode state machine 828 resets the source mode OI detection signal to indicate that the detected source mode OI event has cleared.

FIG. 15 is a schematic diagram of the sink mode state machine 830 of FIG. 8, according to an embodiment of the present disclosure. In the example of FIG. 15, the sink mode state machine 830 includes example level shifters 1502, 1504, 1506 to level shift down the drive signals for the switches 202, 204. For example, the level shifters 1502, 1504 level shift down the drive signal for the switch 204 and the level shifter 1506 level shifts down the drive signal for the switch 202. Additionally, the sink mode state machine 830 includes programmable delay deglitching circuits 1508, 1510, 1512 to deglitch the level shifted drive signals. For example, the programmable delay deglitching circuits 1508, 1510 deglitch the level shifted drive signal for the switch 204 and the programmable delay deglitching circuit 1512 deglitches the level shifted drive signal for the switch 202. In the example of FIG. 15, the sink mode state machine 830 includes example delay circuits 1514, 1516, 1518 that introduce a delay to the level shifted, deglitched drive signals. For example, the delay circuits 1514, 1516 delay the level shifted deglitched drive signal for the switch 204 and the delay circuit 1518 delays the level shifted deglitched drive signal for the switch 202.

In the illustrated example of FIG. 15, the sink mode state machine 830 includes a first AND gate 1520 to perform a logic AND operation on the level shifted, deglitched, delayed drive signal for the switch 204 and the OI sink mode signal (identified as OI_SNK_COMP). In the example of FIG. 15, the output of the AND gate 1520 drives the clock input of a first flip-flop 1522 having a data input coupled to the supply terminal 212 and a clear input coupled to the output of the programmable delay deglitching circuit 1508. The output of the flip-flop 1522 drives the set input of a set, reset (SR) latch 1524.

In the illustrated example of FIG. 15, the sink mode state machine 830 also includes a second AND gate 1526 to perform a logic AND operation on the level shifted, deglitched, delayed drive signal for the switch 204 and the low-side UI sink mode signal (identified as UI_SNK_COMP). In the example of FIG. 15, the output of the AND gate 1526 drives the clock input of a second flip-flop 1528 having a data input coupled to the supply terminal 212 and a clear input coupled to the output of the programmable delay deglitching circuit 1510. The output of the flip-flop 1528 drives a first input of an OR gate 1530.

In the illustrated example of FIG. 15, the sink mode state machine 830 includes a third AND gate 1532 to perform a logic AND operation on the level shifted, deglitched, delayed drive signal for the switch 202 and the high-side UI sink mode signal (identified as HS_UI_SNK_COMP). In the example of FIG. 15, the output of the AND gate 1532 drives the clock input of a third flip-flop 1534 having a data input coupled to the supply terminal 212 and a clear input coupled to the output of the programmable delay deglitching circuit 1512. The output of the flip-flop 1534 drives a second input of the OR gate 1530. In the example of FIG. 15, the output of the OR gate 1530 drives the reset input of the SR latch 1524. Additionally, the output of the SR latch 1524 provides the sink mode OI detection signal (identified as OI_SNK_VD).

In the illustrated example of FIG. 15, responsive to the OI sink mode signal indicating that a sink mode OI event was detected and a close value on the drive signal for the switch 204 (e.g., indicating the switch 204 is to be closed), the sink mode state machine 830 sets the sink mode OI detection signal to indicate that a sink mode OI event was detected. Responsive to the low-side UI sink mode signal indicating that a low-side sink mode UI event was detected and a close value on the drive signal for the switch 204 (e.g., indicating the switch 204 is to be closed), the sink mode state machine 830 resets the sink mode OI detection signal to indicate that the detected sink mode OI event has cleared. Additionally or alternatively, responsive to the high-side UI sink mode signal indicating that a high-side sink mode UI event was detected and a close value on the drive signal for the switch 202 (e.g., indicating the switch 202 is to be closed), the sink mode state machine 830 resets the sink mode OI detection signal to indicate that the detected sink mode OI event has cleared.

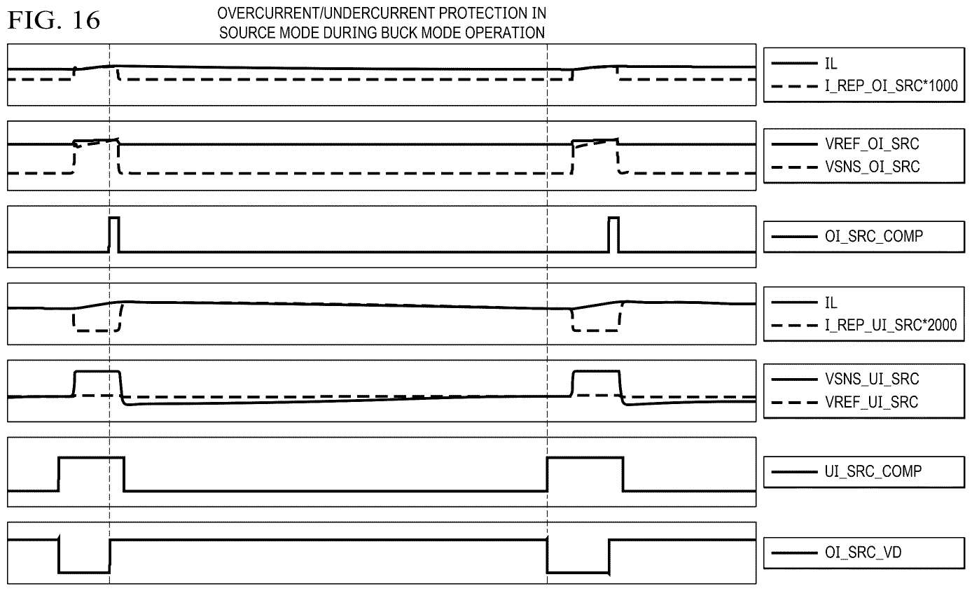

FIG. 16 is a timing diagram depicting example UI protection and OI protection of the driver power stage 104 of FIG. 2 in source mode during buck mode operation, according to an embodiment of the present disclosure. In the example of FIG. 16, the timing diagram depicts signals corresponding to a voltage at the supply terminal 212 of 3.3V (e.g., AVDD=3.3V) with the driver power stage 104 in buck mode, a source mode OI limit of 3.45 A, and a source mode UI limit of 2.75 A. Additionally, the timing diagram of FIG. 16 depicts signals corresponding to the output terminal of the driver power stage 104 being shorted to ground (e.g., via a 5 milliohm (mΩ) resistor).

In the illustrated example of FIG. 16, the first row of the timing diagram depicts the current through the inductor 210 (identified as IL) and the scaled version of the current through the replica transistor 902 (identified as I_REP_OI_SRC*1000). Additionally, the second row of the timing diagram of FIG. 16 depicts the voltage at the output of the high-side source mode sensor 806 (identified as VSNS_OI_SRC) and the source mode OI reference voltage (identified as VREF_OI_SRC). In the example of FIG. 16, the third row of the timing diagram depicts the OI source mode signal (identified as OI_SRC_COMP) provided by the high-side source mode OI comparator 808.

In the illustrated example of FIG. 16, the fourth row of the timing diagram depicts the current through the inductor 210 (identified as IL) and the scaled version of the current through the replica transistor 1102 (identified as I_REP_UI_SRC*2000). Additionally, the fifth row of the timing diagram of FIG. 16 depicts the voltage at the output of the low-side source mode sensor 810 (identified as VSNS_UI_SRC) and the source mode UI reference voltage (identified as VREF_UI_SRC). In the example of FIG. 16, the sixth row of the timing diagram depicts the UI source mode signal (identified as UI_SRC_COMP) provided by the low-side source mode UI comparator 812.

In the illustrated example of FIG. 16, the seventh row of the timing diagram depicts the source mode OI detection signal (identified as OI_SRC_VD) provided by the source mode state machine 828. As described above, the source mode state machine 828 generates the source mode OI detection signal as the deglitched and latched version of the OI source mode signal and the UI source mode signal. As illustrated in FIG. 16, the voltage at the output of the high-side source mode sensor 806 and the voltage at the output of the low-side source mode sensor 810 track the current through the inductor 210 very closely.

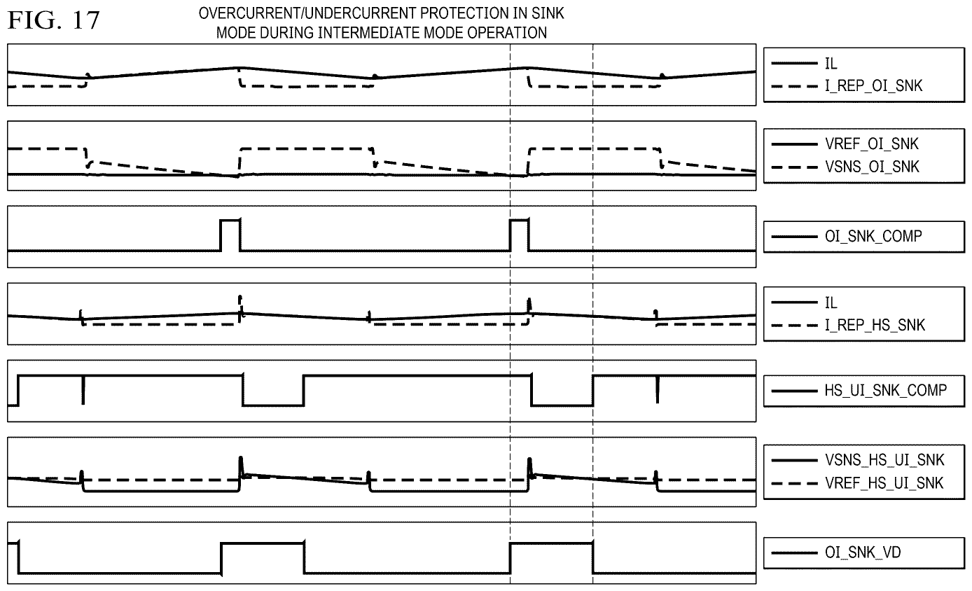

FIG. 17 is a timing diagram depicting example UI protection and OI protection of the driver power stage 104 of FIG. 2 in sink mode during intermediate mode operation, according to an embodiment of the present disclosure. In the example of FIG. 17, the timing diagram depicts signals corresponding to a voltage at the supply terminal 212 of 3.3V (e.g., AVDD=3.3V) with the driver power stage 104 in intermediate mode, a sink mode OI limit of −3.45 A, and a high-side sink mode UI limit of −2.75 A. Additionally, the timing diagram of FIG. 17 depicts signals corresponding to the output terminal of the driver power stage 104 being shorted to ground (e.g., via a 5 mΩ resistor).

In the illustrated example of FIG. 17, the first row of the timing diagram depicts the current through the inductor 210 (identified as IL) and the scaled version of the current through the replica transistor 1202 (identified as I_REP_OI_SNK). In the example of FIG. 17, the current through the inductor 210 and the current through the replica transistor 1202 are illustrated with positive values for ease of understanding. In sink mode, the current through the inductor 210 and the current through the replica transistor 1202 are negative as described above. In the example of FIG. 17, the second row of the timing diagram depicts the voltage at the output of the low-side sink mode sensor 814 (identified as VSNS_OI_SNK) and the sink mode OI reference voltage (identified as VREF_OI_SNK). Additionally, the third row of the timing diagram of FIG. 17 depicts the OI sink mode signal (identified as OI_SNK_COMP) provided by the low-side sink mode OI comparator 816.

In the illustrated example of FIG. 17, the fourth row of the timing diagram depicts the current through the inductor 210 (identified as IL) and the scaled version of the current through the replica transistor 1302 (identified as I_REP_UI_SNK). In the example of FIG. 17, the current through the inductor 210 and the current through the replica transistor 1302 are illustrated with positive values for ease of understanding. In sink mode, the current through the inductor 210 and the current through the replica transistor 1302 are negative as described above. In the example of FIG. 17, the fifth row of the timing diagram depicts the high-side UI sink mode signal (identified as HS_UI_SNK_COMP) provided by the high-side sink mode UI comparator 822. Additionally, the sixth row of the timing diagram of FIG. 17 depicts the voltage at the output of the high-side sink mode sensor 820 (identified as VSNS_UI_SNK) and the high-side sink mode UI reference voltage (identified as VREF_HS_UI_SNK).

In the illustrated example of FIG. 17, the seventh row of the timing diagram depicts the sink mode OI detection signal (identified as OI_SNK_VD) provided by the sink mode state machine 830. As described above, the sink mode state machine 830 generates the sink mode OI detection signal as the deglitched and latched version of the OI sink mode signal and the high-side UI sink mode signal. As illustrated in FIG. 17, the voltage at the output of the low-side sink mode sensor 814 and the voltage at the output of the high-side sink mode sensor 820 track the current through the inductor 210 very closely.

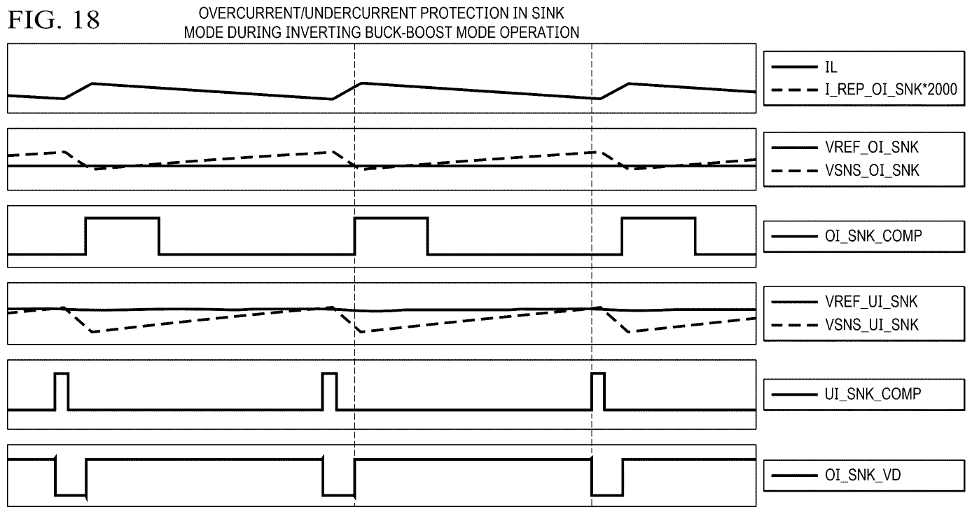

FIG. 18 is a timing diagram depicting example UI protection and OI protection of the driver power stage 104 of FIG. 2 in sink mode during inverting buck-boost mode operation, according to an embodiment of the present disclosure. In the example of FIG. 18, the timing diagram depicts signals corresponding to a voltage at the supply terminal 212 of 3.3V (e.g., AVDD=3.3V) with the driver power stage 104 in inverting buck-boost mode, a sink mode OI limit of −3.45 A, and a low-side sink mode UI limit of −2.75 A. Additionally, the timing diagram of FIG. 18 depicts signals corresponding to the output terminal of the driver power stage 104 being shorted to ground (e.g., via a 5 mΩ resistor).

In the illustrated example of FIG. 18, the first row of the timing diagram depicts the current through the inductor 210 (identified as IL) and the scaled version of the current through the replica transistor 1202 (identified as I_REP_OI_SNK*2000). As illustrated in FIG. 18, the current through the replica transistor 1202 is continuous in sink mode during inverting buck-boost mode operation. As described above, for ease of understanding, the current through the inductor 210 and the current through the replica transistor 1202 are illustrated with positive values. In sink mode, the current through the inductor 210 and the current through the replica transistor 1202 are negative as described above. In the example of FIG. 18, the second row of the timing diagram depicts the voltage at the output of the low-side sink mode sensor 814 (identified as VSNS_OI_SNK) and the sink mode OI reference voltage (identified as VREF_OI_SNK). Additionally, the third row of the timing diagram of FIG. 18 depicts the OI sink mode signal (identified as OI_SNK_COMP) provided by the low-side sink mode OI comparator 816.

In the illustrated example of FIG. 18, the fourth row of the timing diagram depicts the voltage at the output of the low-side sink mode sensor 814 (identified as VSNS_UI_SNK) and the low-side sink mode UI reference voltage (identified as VREF_UI_SNK). Additionally, the fifth row of the timing diagram of FIG. 18 depicts the low-side UI sink mode signal (identified as UI_SNK_COMP) provided by the low-side sink mode UI comparator 818. In the example of FIG. 18, the sixth row of the timing diagram depicts the sink mode OI detection signal (identified as OI_SNK_VD) provided by the sink mode state machine 830. As described above, the sink mode state machine 830 generates the sink mode OI detection signal as the deglitched and latched version of the OI sink mode signal and the low-side UI sink mode signal.

As described above, the example OI current sensor subsystem 804 (e.g., an overcurrent protection circuit) implements a bi-directional cycle-by-cycle current limit for the driver power stage 104 that controls inductor current seamlessly in the three modes of the operation of the driver power stage 104. Additionally, the OI current sensor subsystem 804 is lossless and does not require an off-chip, high-power, precision resistor for current sensing. The lossless sensing of the OI current sensor subsystem 804 facilitates a peak power efficiency of >92% for the driver power stage 104.

Additionally, example calibration described herein reduces offset requirements for the high-side source mode sensor 806, the high-side source mode OI comparator 808, the low-side sink mode sensor 814, and for the low-side sink mode OI comparator 816 which allows for a more compact design. In examples described herein, the accuracy of the OI current sensor subsystem 804 (e.g., ±25 mA or <±2.5%) facilitates increased (e.g., maximized) output power to the TEC element 102 by supporting a higher peak current through the inductor 210. Furthermore, the accuracy of the OI current sensor subsystem 804 allows the driver power stage 104 to be used with a wide range of saturation current values for the inductor 210.

While an example manner of implementing the system 800 of FIG. 8 is illustrated in FIGS. 8-15, one or more of the elements, processes, and/or devices illustrated in FIGS. 8-15 may be combined, divided, re-arranged, omitted, eliminated, and/or implemented in any other way. Further, one or more of the elements, processes, and/or devices of FIGS. 8-15, may be implemented by hardware alone or by hardware in combination with software and/or firmware. Thus, for example, any of the elements, processes, and/or devices of FIGS. 8-15, could be implemented by one or more programmable circuits, processor circuits, analog circuit(s), digital circuits, logic circuits, programmable processors, programmable microcontroller(s), graphics processing unit(s) (GPU(s)), digital signal processor(s) (DSP(s)), ASIC(s), programmable logic device(s) (PLD(s)), vision processing units (VPUs), and/or field programmable logic device(s) (FPLD(s)) such as FPGAs in combination with machine-readable instructions (e.g., firmware or software). Further still, the elements, processes, and/or devices of FIGS. 8-15 may include one or more elements, processes, and/or devices in addition to, or instead of, those illustrated in FIGS. 8-15, and/or may include more than one of any or all of the illustrated elements, processes, and devices.

Additionally or alternatively, one or more of the elements, processes, and/or devices illustrated in FIGS. 8-15 may be implemented by example machine-readable instructions, which may be executed by one or more programmable circuits to implement and/or instantiate one or more of the elements, processes, and/or devices illustrated in FIGS. 8-15 and/or may be performed by one or more programmable circuits to implement and/or instantiate one or more of the elements, processes, and/or devices illustrated in FIGS. 8-15. The machine-readable instructions may be one or more executable programs or portion(s) of one or more executable programs for execution by one or more programmable circuits. In some examples, the machine-readable instructions cause an operation, a task, etc., to be carried out and/or performed in an automated manner in the real world. In some examples, “automated” means without human involvement.

The program may be embodied in instructions (e.g., software and/or firmware) stored on one or more non-transitory computer-readable and/or machine-readable storage medium.

Although the example program is described with reference to the elements, processes, and/or devices illustrated in FIGS. 8-15, many other methods of implementing the system 800 of FIG. 8 may alternatively be used. For example, the order of execution of the elements, processes, and/or devices illustrated in FIGS. 8-15 may be changed, and/or some of the elements, processes, and/or devices illustrated in FIGS. 8-15 may be changed, eliminated, or combined. Additionally or alternatively, any or all of the elements, processes, and/or devices illustrated in FIGS. 8-15 may be implemented by one or more hardware circuits (e.g., one or more processor circuits, one or more discrete analog circuits, one or more integrated analog circuits, one or more discrete digital circuits, one or more integrated digital circuits, an FPGA, an ASIC, a comparator, an operational-amplifier (op-amp), a logic circuit, etc.) structured to perform the corresponding operation without executing software or firmware. The one or more programmable circuits may be distributed in different network locations and/or local to one or more hardware devices (e.g., a single-core processor (e.g., a single core CPU), a multi-core processor (e.g., a multi-core CPU, an XPU, etc.)).

From the foregoing, it will be appreciated that example systems, apparatus, articles of manufacture, and methods have been described include a four switch topology that utilizes a single inductor and a single capacitor, saving board space and cost, to drive a TEC element in a single-ended manner with one end of the TEC element grounded. Examples described herein include three switching modes to achieve very low zero-crossing glitch with high overall efficiency. Depending on the switching mode, the example four switch topology described herein can generate positive voltages, negative voltages, or both positive and negative voltages across a TEC element in a seamless way to ensure a glitch-free zero-crossing.

For example, the described four switch topology operates in intermediate mode having a specific switching sequence and a duty cycle of 0.5 to generate an output voltage of 0V. As such, examples described herein avoid abrupt changes, either in duty cycle or in switching mode, near zero-crossings. Accordingly, examples described herein provide seamless transition from negative output to positive output (and vice versa) leading to glitch-free zero-crossing.

Examples described herein also include an example overcurrent protection circuit that reliably limits the inductor current in both positive and negative directions without the use of an external sense resistor. As such, the example overcurrent protection circuit described herein incurs minimal efficiency loss and provides low sensing error. Additionally, the example overcurrent protection circuit described herein handles overcurrent events (such as short circuits) in the above-described three modes of operation. Additionally, by operating on the low voltage switching node (e.g., the node SW1), the example overcurrent protection circuit described herein reduces area consumption because relatively smaller, lower voltage transistors can be used to monitor current compared to if the example over current protection circuit operated on the high voltage switching node (e.g., the node SW2).

Example embodiments of the present disclosure are summarized here. Other embodiments can also be understood from the entirety of the specification and the claims filed herein.

Example 1. An electronic circuit including: first and second supply terminals; first and second inductor terminals; an output terminal; a first switch coupled between the first supply terminal and the first inductor terminal; a second switch coupled between the first inductor terminal and the second supply terminal; a third switch coupled between the first supply terminal and the second inductor terminal; a fourth switch coupled between the second inductor terminal and the output terminal; and a controller configured to: when an output voltage at the output terminal is higher than a first threshold, close the fourth switch, open the third switch, and operate the first and second switches in alternate phases; when the output voltage is lower than a second threshold that is lower than the first threshold, close the second switch, open the first switch, and operate the third and fourth switches in alternate phases; and when the output voltage is between the first and second thresholds, operate the first and fourth switches according to a first clock signal, and operate the second and third switches according to a second clock signal that is non-overlapping with respect to the first clock signal.

Example 2. The electronic circuit of example 1, where the controller is configured to regulate the output voltage by adjusting a duty cycle of the first clock signal when the output voltage is between the first and second thresholds.

Example 3. The electronic circuit of one of examples 1 or 2, where the controller is configured to generate the first clock signal having a fixed frequency, and the second clock signal having the fixed frequency.

Example 4. The electronic circuit of one of examples 1 to 3, where the first, second, third, and fourth switches are n-channel metal-oxide semiconductor field-effect transistors.

Example 5. The electronic circuit of one of examples 1 to 4, where the first and third switches are p-channel metal-oxide semiconductor field-effect transistors, and the second and fourth switches are n-channel metal-oxide semiconductor field-effect transistors.

Example 6. The electronic circuit of one of examples 1 to 5, where the second supply terminal is a ground terminal, where the first threshold is a positive voltage, and where the second threshold is a negative voltage.

Example 7. The electronic circuit of one of examples 1 to 6, further including a thermoelectric cooler (TEC) element coupled between the output terminal and the second supply terminal.

Example 8. The electronic circuit of one of examples 1 to 7, further includes an inductor coupled between the first and second inductor terminals.

Example 9. The electronic circuit of one of examples 1 to 8, where the controller has first, second, third, and fourth outputs, and: the first switch has a first current path terminal coupled to the first supply terminal, a second current path terminal coupled to the first inductor terminal, and a control terminal coupled to the first output of the controller; the second switch has a first current path terminal coupled to the first inductor terminal, a second current path terminal coupled to the second supply terminal, and a control terminal coupled to the second output of the controller; the third switch has a first current path terminal coupled to the first supply terminal, a second current path terminal coupled to the second inductor terminal, and a control terminal coupled to the third output of the controller; and the fourth switch has a first current path terminal coupled to the second inductor terminal, a second current path terminal coupled to the output terminal, and a control terminal coupled to the fourth output of the controller.

Example 10. An electronic circuit including: first and second supply terminals; first and second inductor terminals; an output terminal coupled to the second inductor terminal; a first transistor having a current path coupled between the first supply terminal and the first inductor terminal; a second transistor having a current path coupled between the first inductor terminal and the second supply terminal; and a current sensing circuit including: a third transistor having a control terminal coupled to a control terminal of the first transistor, and a first current path terminal coupled to the first supply terminal; a first amplifier having a first input coupled to a second current path terminal of the third transistor, and a second input coupled to the current path of the first transistor; a fourth transistor having a first current path terminal coupled to the second current path terminal of the third transistor, and a control terminal coupled to an output of the first amplifier; a second amplifier having a first input coupled to a second current path terminal of the fourth transistor; and a first resistor coupled to the second current path terminal of the fourth transistor.

Example 11. The electronic circuit of example 10, further including a calibration circuit including: a fifth transistor having a current path coupled between the current path of the first transistor and the second input of the first amplifier, and a control terminal coupled to the control terminals of the first and third transistors; a current mirror having a first input coupled to the current path of the fifth transistor; a first switch having a first current path terminal, a second current path terminal, and a control terminal, the second current path terminal coupled to a second input of the current mirror; a first current source having an output coupled to the first current path terminal of the first switch; a second resistor coupled between an output of the current mirror and the second supply terminal; a third resistor coupled between the output of the current mirror and a second input of the second amplifier; a second switch have a first current path terminal and a second current path terminal, the second current path terminal coupled to the second input of the second amplifier; and a second current source having an output coupled to the first current path terminal of the second switch.

Example 12. The electronic circuit of one of examples 10 or 11, where the third resistor is a variable resistor.

Example 13. The electronic circuit of one of examples 10 to 12, where a resistance of the second resistor is equal to a resistance of the first resistor.

Example 14. The electronic circuit of one of examples 10 to 13, further including a controller having an output coupled to a third input of the second amplifier.

Example 15. The electronic circuit of one of examples 10 to 14, where the current sensing circuit is a first current sensing circuit, and the electronic circuit further includes a second current sensing circuit including: a fifth transistor having a first current path terminal, a second current path terminal, and a control terminal, the first current path terminal coupled to the current path of the second transistor, the control terminal coupled to a control terminal of the second transistor; a sixth transistor having a first current path terminal, a second current path terminal coupled to the second supply terminal, and a control terminal coupled to the first supply terminal; a third amplifier having a first input coupled to the second current path terminal of the fifth transistor and a second input coupled to the second current path terminal of the sixth transistor; a seventh transistor having a first current path terminal coupled to the second current path terminal of the fifth transistor, and a control terminal coupled to an output of the third amplifier; a fourth amplifier having a first input coupled to a second current path terminal of the seventh transistor; and a second resistor coupled to the second current path terminal of the seventh transistor.

Example 16. The electronic circuit of one of examples 10 to 15, further including: an inductor having a first terminal coupled to the first inductor terminal and a second terminal coupled to the second inductor terminal; and an output capacitor having a terminal coupled to the second terminal of the inductor, the first current sensing circuit to monitor for an overcurrent event associated with the first transistor, the second current sensing circuit to monitor for an undercurrent event associated with the second transistor.

Example 17. The electronic circuit of one of examples 10 to 16, further including: a fifth transistor having a current path coupled between the first supply terminal and the second inductor terminal; a sixth transistor having a current path coupled between the second inductor terminal and the output terminal; an inductor coupled between the first inductor terminal and the second inductor terminal; and a thermoelectric cooler element coupled between the output terminal and the second supply terminal.

Example 18. A method including: operating first and second switches with a fixed switching frequency to regulate an output voltage at an output terminal, where the first switch is coupled between a first supply terminal and a first inductor terminal, where the second switch is coupled between the first inductor terminal and a second supply terminal, where an inductor is coupled between the first inductor terminal and a second inductor terminal, and where the output terminal is coupled to the second inductor terminal; in response to inductor current through the inductor being higher than a first current threshold, turning off the first switch and turning on the second switch to start a first discharge phase of the inductor; during the first discharge phase of the inductor, maintain the first switch off and the second switch on; and in response to the inductor current dropping below a second current threshold that is lower than the first current threshold, restarting operation of the first and second switches with the fixed switching frequency to exit the first discharge phase.

Example 19. The method of example 18, further including: determining the inductor current during a charge phase of the inductor based on sensing a current flowing through the first switch; and determining the inductor current during the first discharge phase of the inductor based on sensing a current flowing through the second switch.

Example 20. The method of one of examples 18 or 19, further including, in response to the output voltage being higher than a voltage threshold: turning off a third switch and turning on a fourth switch, where the third switch is coupled between the first supply terminal and the second inductor terminal, where the fourth switch is coupled between the second inductor terminal and the output terminal; and operating the first and second switches in alternate phases.

Example 21. The method of one of examples 18 to 20, further including: operating the first and second switches and third and fourth switches with the fixed switching frequency to regulate the output voltage, where the third switch is coupled between the first supply terminal and the second inductor terminal, where the fourth switch is coupled between the second inductor terminal and the output terminal; in response to the inductor current dropping below a third current threshold while the second and third switches are on, turning off the second and third switches and turning on the first and fourth switches to start a second discharge phase of the inductor; during the second discharge phase of the inductor, maintaining the second and third switches off and the first and fourth switches on; and in response to the inductor current being higher than a fourth current threshold that is higher than the third current threshold, restarting operation of the second and third switches with the fixed switching frequency to exit the second discharge phase.

Example 22. The method of one of examples 18 to 21, further including: in response to the output voltage being less than a voltage threshold, turning on the second switch, turning off the first switch, and operating third and fourth switches in alternate phases, where the third switch is coupled between the first supply terminal and the second inductor terminal, where the fourth switch is coupled between the second inductor terminal and the output terminal; in response to the inductor current dropping below a third current threshold while the second and third switches are on, turning off the third switch and turning on the fourth switch to start a second discharge phase of the inductor; during the second discharge phase of the inductor, maintaining the third switch off and the second and fourth switches on; and in response to the inductor current being higher than a fourth current threshold that is higher than the third current threshold, restarting operation of the second and third switches with the fixed switching frequency and alternate phases to exit the second discharge phase.

Example 23. The method of one of examples 18 to 22, where sensing the current flowing through the first switch includes: applying a voltage to a control terminal of a first transistor that is equal to a voltage applied to a control terminal of the first switch; forcing a voltage at a second current path terminal of the first transistor to be equal to a voltage at a second current path terminal of the first switch to replicate a current flowing through the first switch at the first transistor; and applying the replicated current to a first resistor to convert the replicated current to a voltage; and comparing, with an amplifier, the voltage to a reference voltage that is proportional to a first reference current.

Example 24. The method of one of examples 18 to 23, where a size of the first transistor matches a size of the first switch.

Example 25. The method of one of examples 18 to 24, further including calibrating the amplifier to compensate for error introduced by at least matching between the first transistor and the first switch, matching between the current and the replicated current, and the amplifier.

Example 26. The method of one of examples 18 to 25, where calibrating the first reference current includes: turning on the first switch and a third switch to set the inductor current to zero, where the third switch is coupled between the first supply terminal and the second inductor terminal; turning on a calibration switch to cause a current mirror to induce a calibration current through a second transistor to sample the calibration current, the second transistor matched to the first transistor; applying the calibration current to a second resistor to generate a reference voltage; replicating the calibration current through the first transistor; applying the replicated calibration current to the first resistor to generate a sensed voltage; comparing the reference voltage to the sensed voltage; and applying one or more trim codes to the amplifier until the amplifier changes an output state based on the reference and sensed voltages.

Example 27. The method of one of examples 18 to 26, where a resistance of the first resistor is equal to a resistance of the second resistor.

Example 28. The method of one of examples 18 to 27, where the calibration switch is turned off when the first switch and the second switch are operating in a normal mode.

Example 29. An electronic circuit including: first and second supply terminals; first and second inductor terminals; an output terminal coupled to the second inductor terminal; a first transistor having a current path coupled between the first supply terminal and the first inductor terminal; a second transistor having a current path coupled between the first inductor terminal and the second supply terminal; and a current sensing circuit including: a third transistor having a first current path terminal, a second current path terminal, and a control terminal coupled to a control terminal of the second transistor, the second current path terminal coupled to the second supply terminal; a first amplifier having a first input coupled to the first current path terminal of the third transistor, and a second input coupled to the current path of the second transistor; a fourth transistor having a first current path terminal coupled to the first current path terminal of the third transistor, and a control terminal coupled to an output of the first amplifier; a second amplifier having a first input coupled to a second current path terminal of the fourth transistor; and a first resistor coupled to the second current path terminal of the fourth transistor.

Example 30. The electronic circuit of example 29, where the first amplifier includes: a first n-channel metal-oxide semiconductor (NMOS) transistor having a source terminal, a drain terminal, and a gate terminal, the source terminal coupled to the first current path terminal of the third transistor, the drain terminal coupled to the control terminal of the fourth transistor; and a second NMOS transistor having a source terminal, a drain terminal, and a gate terminal, the source terminal coupled to the current path of the second transistor, the drain terminal coupled to the gate terminals of the first NMOS transistor and second NMOS transistor.

Example 31. The electronic circuit of one of examples 29 or 30, further including a calibration circuit including: a fifth transistor having a current path coupled between the current path of the second transistor and the second input of the first amplifier, and a control terminal coupled to the first supply terminal; a current mirror having a first input coupled to the current path of the fifth transistor; a first switch having a first current path terminal, a second current path terminal, and a control terminal, the second current path terminal coupled to a second input of the current mirror; a first current source having an output coupled to the first current path terminal of the first switch; a second resistor coupled between an output of the current mirror and the first supply terminal; a third resistor coupled between the output of the current mirror and a second input of the second amplifier; a second switch have a first current path terminal and a second current path terminal, the second current path terminal coupled to the second input of the second amplifier; and a second current source having an output coupled to the first current path terminal of the second switch.

Example 32. The electronic circuit of one of examples 29 to 31, where a resistance of the second resistor is equal to a resistance of the first resistor.

Example 33. The electronic circuit of one of examples 29 to 32, where the current mirror includes: a first p-channel metal-oxide semiconductor (PMOS) transistor having a source terminal, a drain terminal, and a gate terminal, the drain terminal coupled to the second current path terminal of the fifth transistor, the source terminal coupled to the second resistor; and a second PMOS transistor having a source terminal, a drain terminal, and a gate terminal, the drain terminal coupled to the second current path terminal of the first switch and to the gate terminals of the first PMOS transistor and the second PMOS transistor, the source terminal is coupled to a fourth resistor.

Example 34. The electronic circuit of one of examples 29 to 33, where the current sensing circuit is a first current sensing circuit, and the electronic circuit further includes a second current sensing circuit including: a fifth transistor having a first current path terminal, a second current path terminal, and a control terminal, the second current path terminal coupled to the current path of the first transistor, the control terminal coupled to a control terminal of the first transistor; a third amplifier having a first input, coupled to the first current path terminal of the fifth transistor and a second input coupled to the current path of the first transistor; a sixth transistor having a first current path terminal coupled to the first current path terminal of the fifth transistor and a control terminal coupled to an output of the third amplifier; a fourth amplifier having a first input coupled to a second current path terminal of the sixth transistor; and a second resistor coupled to the second current path terminal of the sixth transistor.

Example 35. The electronic circuit of one of examples 29 to 34, where a size of the fifth transistor matches a size of the first transistor.

Example 36. The electronic circuit of one of examples 29 to 35, where a size of the third transistor matches a size of the second transistor.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. An electronic circuit comprising:
first and second supply terminals;
first and second inductor terminals;
an output terminal;
a first switch coupled between the first supply terminal and the first inductor terminal;
a second switch coupled between the first inductor terminal and the second supply terminal;
a third switch coupled between the first supply terminal and the second inductor terminal;
a fourth switch coupled between the second inductor terminal and the output terminal; and
a controller configured to:
when an output voltage at the output terminal is higher than a first threshold, close the fourth switch, open the third switch, and operate the first and second switches in alternate phases;
when the output voltage is lower than a second threshold that is lower than the first threshold, close the second switch, open the first switch, and operate the third and fourth switches in alternate phases; and
when the output voltage is between the first and second thresholds, operate the first and fourth switches according to a first clock signal, and operate the second and third switches according to a second clock signal that is non-overlapping with respect to the first clock signal.

2. The electronic circuit of claim 1, wherein the controller is configured to regulate the output voltage by adjusting a duty cycle of the first clock signal when the output voltage is between the first and second thresholds.

3. The electronic circuit of claim 1, wherein the controller is configured to generate the first clock signal having a fixed frequency, and the second clock signal having the fixed frequency.

4. The electronic circuit of claim 1, wherein the first, second, third, and fourth switches are n-channel metal-oxide semiconductor field-effect transistors.

5. The electronic circuit of claim 1, wherein the first and third switches are p-channel metal-oxide semiconductor field-effect transistors, and the second and fourth switches are n-channel metal-oxide semiconductor field-effect transistors.

6. The electronic circuit of claim 1, wherein the second supply terminal is a ground terminal, wherein the first threshold is a positive voltage, and wherein the second threshold is a negative voltage.

7. The electronic circuit of claim 1, further comprising a thermoelectric cooler (TEC) element coupled between the output terminal and the second supply terminal.

8. The electronic circuit of claim 1, further comprises an inductor coupled between the first and second inductor terminals.

9. The electronic circuit of claim 1, wherein the controller has first, second, third, and fourth outputs, and:
the first switch has a first current path terminal coupled to the first supply terminal, a second current path terminal coupled to the first inductor terminal, and a control terminal coupled to the first output of the controller;
the second switch has a first current path terminal coupled to the first inductor terminal, a second current path terminal coupled to the second supply terminal, and a control terminal coupled to the second output of the controller;
the third switch has a first current path terminal coupled to the first supply terminal, a second current path terminal coupled to the second inductor terminal, and a control terminal coupled to the third output of the controller; and
the fourth switch has a first current path terminal coupled to the second inductor terminal, a second current path terminal coupled to the output terminal, and a control terminal coupled to the fourth output of the controller.

10. A method comprising:
operating first and second switches with a fixed switching frequency to regulate an output voltage at an output terminal, wherein the first switch is coupled between a first supply terminal and a first inductor terminal, wherein the second switch is coupled between the first inductor terminal and a second supply terminal, wherein an inductor is coupled between the first inductor terminal and a second inductor terminal, and wherein the output terminal is coupled to the second inductor terminal;
in response to inductor current through the inductor being higher than a first current threshold, turning off the first switch and turning on the second switch to start a first discharge phase of the inductor;
during the first discharge phase of the inductor, maintain the first switch off and the second switch on; and
in response to the inductor current dropping below a second current threshold that is lower than the first current threshold, restarting operation of the first and second switches with the fixed switching frequency to exit the first discharge phase.

11. The method of claim 10, further comprising:
determining the inductor current during a charge phase of the inductor based on sensing a current flowing through the first switch; and
determining the inductor current during the first discharge phase of the inductor based on sensing a current flowing through the second switch.

12. The method of claim 11, wherein sensing the current flowing through the first switch includes:
applying a voltage to a control terminal of a first transistor that is equal to a voltage applied to a control terminal of the first switch;
forcing a voltage at a second current path terminal of the first transistor to be equal to a voltage at a second current path terminal of the first switch to replicate a current flowing through the first switch at the first transistor; and
applying the replicated current to a first resistor to convert the replicated current to a voltage; and
comparing, with an amplifier, the voltage to a reference voltage that is proportional to a first reference current.

13. The method of claim 12, wherein a size of the first transistor matches a size of the first switch.

14. The method of claim 12, further including calibrating the amplifier to compensate for error introduced by at least matching between the first transistor and the first switch, matching between the current and the replicated current, and the amplifier.

15. The method of claim 14, wherein calibrating the first reference current includes:
turning on the first switch and a third switch to set the inductor current to zero, wherein the third switch is coupled between the first supply terminal and the second inductor terminal;
turning on a calibration switch to cause a current mirror to induce a calibration current through a second transistor to sample the calibration current, the second transistor matched to the first transistor;
applying the calibration current to a second resistor to generate a reference voltage;
replicating the calibration current through the first transistor;
applying the replicated calibration current to the first resistor to generate a sensed voltage;
comparing the reference voltage to the sensed voltage; and
applying one or more trim codes to the amplifier until the amplifier changes an output state based on the reference and sensed voltages.

16. The method of claim 15, wherein a resistance of the first resistor is equal to a resistance of the second resistor.

17. The method of claim 15, wherein the calibration switch is turned off when the first switch and the second switch are operating in a normal mode.

18. The method of claim 10, further comprising, in response to the output voltage being higher than a voltage threshold:
turning off a third switch and turning on a fourth switch, wherein the third switch is coupled between the first supply terminal and the second inductor terminal, wherein the fourth switch is coupled between the second inductor terminal and the output terminal; and
operating the first and second switches in alternate phases.

19. The method of claim 10, further comprising:
operating the first and second switches and third and fourth switches with the fixed switching frequency to regulate the output voltage, wherein the third switch is coupled between the first supply terminal and the second inductor terminal, wherein the fourth switch is coupled between the second inductor terminal and the output terminal;
in response to the inductor current dropping below a third current threshold while the second and third switches are on, turning off the second and third switches and turning on the first and fourth switches to start a second discharge phase of the inductor;
during the second discharge phase of the inductor, maintaining the second and third switches off and the first and fourth switches on; and
in response to the inductor current being higher than a fourth current threshold that is higher than the third current threshold, restarting operation of the second and third switches with the fixed switching frequency to exit the second discharge phase.

20. The method of claim 10, further comprising:
in response to the output voltage being less than a voltage threshold, turning on the second switch, turning off the first switch, and operating third and fourth switches in alternate phases, wherein the third switch is coupled between the first supply terminal and the second inductor terminal, wherein the fourth switch is coupled between the second inductor terminal and the output terminal;
in response to the inductor current dropping below a third current threshold while the second and third switches are on, turning off the third switch and turning on the fourth switch to start a second discharge phase of the inductor;
during the second discharge phase of the inductor, maintaining the third switch off and the second and fourth switches on; and
in response to the inductor current being higher than a fourth current threshold that is higher than the third current threshold, restarting operation of the second and third switches with the fixed switching frequency and alternate phases to exit the second discharge phase.
